(19) United States
(12) Patent Application Publication
(10) Pub. No.: US 2025/0292805 A1
(43) Pub. Date: Sep. 18, 2025

(54) SEMICONDUCTOR MEMORY DEVICE

(71) Applicant: Samsung Electronics Co., Ltd., Suwon-si (KR)

(72) Inventors: Jihoon CHANG, Suwon-si (KR); Sooho SHIN, Suwon-si (KR); Julpin PARK, Suwon-si (KR); Hyeonwoo JANG, Suwon-si (KR); Yujin CHO, Suwon-si (KR)

(73) Assignee: Samsung Electronics Co., Ltd., Suwon-si (KR)

(21) Appl. No.: 19/010,993

(22) Filed: Jan. 6, 2025

(30) Foreign Application Priority Data
Mar. 13, 2024 (KR) 10-2024-0035433

(51) Int. Cl. G11C 5/06; H10B 12/00

(52) U.S. Cl. CPC G11C 5/06; H10B 12/482; H10B 12/488

(57) ABSTRACT

Provided is a semiconductor memory device including a substrate, a plurality of lower electrodes on the substrate, a support pattern in contact with upper end sidewalls of the plurality of lower electrodes, a capacitor dielectric layer on the plurality of lower electrodes, upper electrodes on the capacitor dielectric layer, a cover insulating layer covering the upper electrode, and a plurality of first wiring contact plugs configured to penetrate the cover insulating layer and extend into the upper electrode, wherein, in a plan view, the plurality of first wiring contact plugs are apart from an edge of the support pattern into the support pattern by at least a first horizontal separation distance, and wherein the first horizontal separation distance is greater than a side surface thickness that is a thickness of a portion of the upper electrode covering side surfaces of the support pattern.

### CROSS-REFERENCE TO RELATED APPLICATION

This application is based on and claims the benefit of priority under 35 U.S.C. § 119 to Korean Patent Application No. 10-2024-0035433, filed on Mar. 13, 2024 in the Korean Intellectual Property office, the disclosure of which is incorporated by reference herein in its entirety for all purposes.

### TECHNICAL FIELD

The inventive concept relates to a semiconductor memory device, and more particularly, to a semiconductor memory device including wiring contact plugs electrically connecting different vertical levels to each other.

### BACKGROUND

Electronic devices have become more compact and lighter according to rapid development of the electronics industry and the demands of users. Accordingly, a high degree of integration is required for semiconductor memory devices used in the electronic devices, and design rules for configurations of the semiconductor memory devices are reduced. Thus, securing reliability of the semiconductor memory devices becomes difficult.

### SUMMARY

The inventive concept provides a semiconductor memory device including wiring contact plugs for securing reliability.

According to an aspect of the inventive concept, there is provided a semiconductor memory device including a substrate including a memory cell region, a plurality of lower electrodes arranged in the memory cell region of the substrate, a support pattern in contact with upper end sidewalls of the plurality of lower electrodes to support the plurality of lower electrodes, a capacitor dielectric layer covering the plurality of lower electrodes and the support pattern, upper electrodes covering the plurality of lower electrodes and the support pattern with the capacitor dielectric layer therebetween, a cover insulating layer covering the upper electrode, a plurality of first wiring contact plugs configured to penetrate the cover insulating layer and extend into the upper electrode, and a plurality of wiring lines arranged on the upper electrode and the plurality of first wiring contact plugs, at least some of the plurality of wiring lines connected to the plurality of first wiring contact plugs, wherein, in a plan view, the plurality of first wiring contact plugs are apart from an edge of the support pattern into the support pattern by at least a first horizontal separation distance, and wherein the first horizontal separation distance is greater than a side surface thickness that is a thickness of a portion of the upper electrode covering side surfaces of the support pattern in a horizontal direction.

According to another aspect of the inventive concept, there is provided a semiconductor memory device including a substrate, a plurality of lower electrodes arranged on the substrate, a support pattern in contact with upper end sidewalls of the plurality of lower electrodes to support the plurality of lower electrodes, a capacitor dielectric layer covering the plurality of lower electrodes and the support pattern, upper electrodes covering the plurality of lower electrodes and the support pattern with the capacitor dielectric layer therebetween, a cover insulating layer covering the upper electrode, in a plan view, a plurality of first wiring contact plugs arranged apart from an edge of the support pattern into the support pattern by at least a first horizontal separation distance, the plurality of first wiring contact plugs configured to penetrate the cover insulating layer and extend into the upper electrode, in a plan view, a plurality of second wiring contact plugs arranged apart from an edge of the support pattern into the support pattern by a second horizontal separation distance less than the first horizontal separation distance, the plurality of first wiring contact plugs configured to penetrate the cover insulating layer and extend into the upper electrode, and a plurality of wiring lines arranged on the upper electrode, the plurality of first wiring contact plugs, and the second wiring contact plug, at least some of the plurality of wiring lines connected to the plurality of first wiring contact plugs and the plurality of second wiring contact plugs, wherein the first horizontal separation distance is greater than a side surface thickness, that is a thickness of a portion of the upper electrode covering side surfaces of the support pattern in a horizontal direction, and wherein a vertical height of each of the plurality of second wiring contact plugs is less than a vertical height of each of the plurality of first wiring contact plugs.

According to another aspect of the inventive concept, there is provided a semiconductor memory device including a substrate in which a plurality of active regions are limited, a plurality of word lines configured to respectively cross the plurality of active regions and extend in a first horizontal direction, a plurality of bit lines respectively arranged in the plurality of active regions, and extending in a second horizontal direction orthogonal to the first horizontal direction, a plurality of buried contacts configured to fill lower side portions of spaces between each of the plurality of bit lines, the plurality of buried contacts respectively connected to the plurality of active regions, a plurality of landing pads configured to fill upper side portions of spaces between each of the plurality of bit lines, the plurality of landing pads respectively extending onto the plurality of bit lines, and a plurality of lower electrodes respectively in contact with the plurality of landing pads, a support pattern in contact with upper end sidewalls of the plurality of lower electrodes to support the plurality of lower electrodes, a capacitor dielectric layer covering the plurality of lower electrodes and the support pattern, upper electrodes covering the plurality of lower electrodes and the support pattern with the capacitor dielectric layer therebetween, a cover insulating layer covering the upper electrode, in a plan view, a plurality of first wiring contact plugs arranged apart from an edge of the support pattern into the support pattern by at least a first horizontal separation distance, the plurality of first wiring contact plugs configured to penetrate the cover insulating layer and extend into the upper electrode, in a plan view, a plurality of second wiring contact plugs arranged apart from an edge of the support pattern into the support pattern by a second horizontal separation distance less than the first horizontal separation distance, the plurality of first wiring contact plugs configured to penetrate the cover insulating layer and extend into the upper electrode, and a plurality of wiring lines arranged on the upper electrode, the plurality of first wiring contact plugs, and the second wiring contact plug, at least some of the plurality of wiring lines connected to the plurality of first wiring contact plugs and the plurality of second wiring contact plugs, wherein the first horizontal separation distance is greater than a side surface thickness, that is a thickness of a portion of the upper electrode covering side surfaces of the support pattern in a horizontal direction, and the second horizontal separation distance is less than the side surface thickness, and wherein a horizontal area of each of the plurality of second wiring contact plugs is less than a horizontal area of each of the plurality of first wiring contact plugs.

### BRIEF DESCRIPTION OF THE DRAWINGS

Embodiments will be more clearly understood from the following detailed description taken in conjunction with the accompanying drawings in which:

FIG. 1A is a block diagram of a semiconductor memory device according to an embodiment, and FIG. 1B is a schematic plan layout of a semiconductor memory device according to an embodiment;

FIGS. 2A through 2H are plan layouts of a semiconductor memory device according to embodiments;

FIGS. 3A through 3D, 4A through 4D, 5A through 5D, 6A through 6D, 7A through 7D, 8A through 8D, 9A through 9D, and 10A through 10D are cross-sectional views for describing a manufacturing method of a semiconductor memory device, according to embodiments, and FIGS. 11A through 11E are cross-sectional views of a semiconductor memory device according to embodiments; and

FIGS. 12 and 13 are respective cross-sectional views of semiconductor memory devices according to embodiments.

### DETAILED DESCRIPTION OF THE EMBODIMENTS

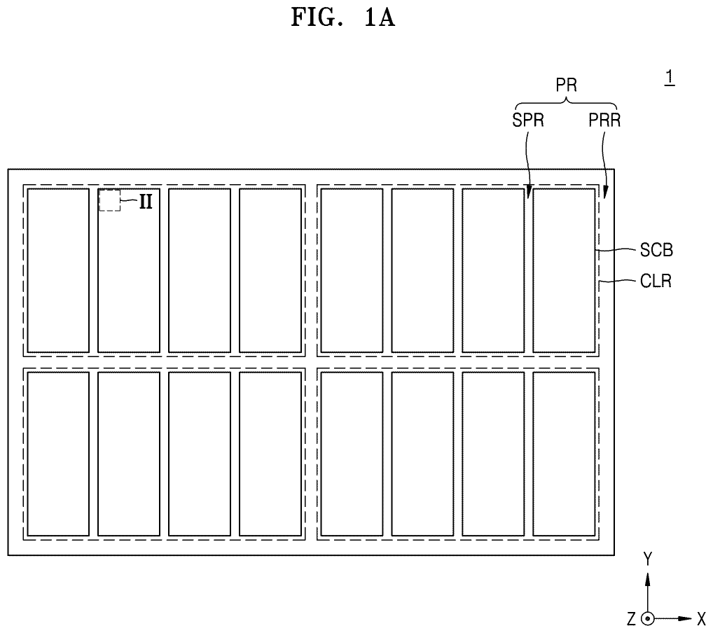

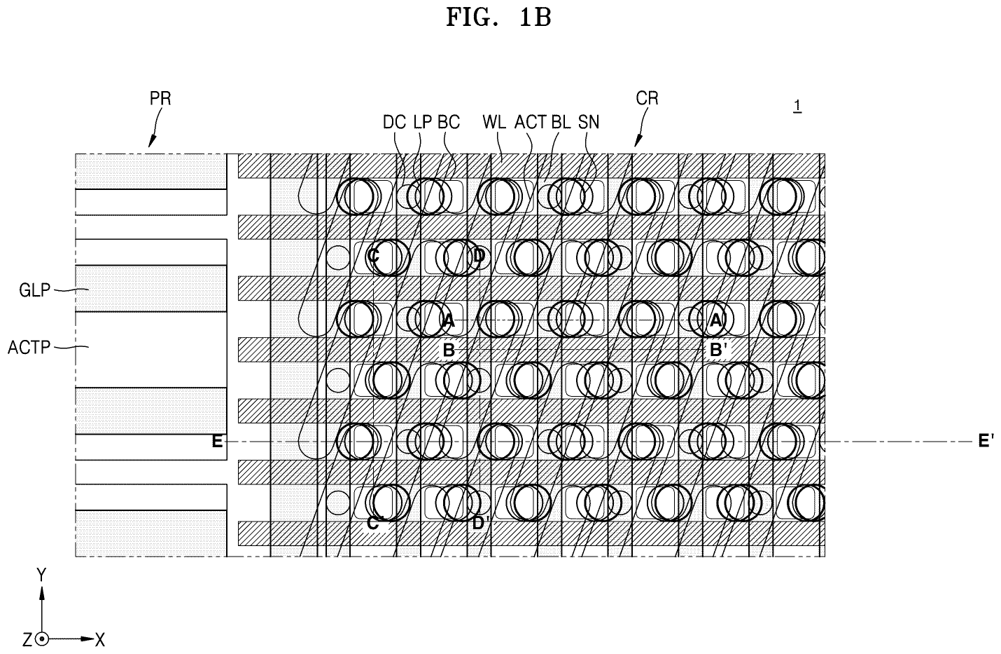

FIG. 1A is a diagram of a semiconductor memory device 1 according to an embodiment, and FIG. 1B is a schematic plan layout of the semiconductor memory device 1 according to an embodiment.

Referring to FIG. 1A, the semiconductor memory device 1 may include a cell region CLR, in which memory cells are arranged, and a main periphery region PRR surrounding the cell region CLR.

According to an embodiment, subperiphery regions SPR dividing cell blocks SCB may be included in the cell region CLR. A plurality of memory cells may be arranged in the cell blocks SCB. In the inventive concept, the cell block SCB may be referred to as a region in which the memory cells are uniformly spaced and regularly arranged, and may be referred to as a subcell block.

Logic cells for receiving/transmitting electrical signals from/to the memory cells may be arranged in the main periphery region PRR and the subperiphery region SPR. In some embodiments, the main periphery region PRR may be referred to as a periphery circuit region, and the subperiphery region SPR may be referred to as a core circuit region. A periphery region PR may include the main periphery region PRR and subperiphery regions SPR. In other words, the periphery region PR may be a core and a peripheral circuit region including the periphery circuit region and the core circuit region. In some embodiments, at least a portion of the subperiphery region SPR may be provided only as a space for distinguishing the cell blocks SCB.

Referring to FIG. 1B, the semiconductor memory device 1 may include a memory cell region CR and a periphery region PR. The semiconductor memory device 1 may include a plurality of active regions ACT formed in the memory cell region CR and a plurality of logic active regions ACTP formed in the periphery region PR. The memory cell region CR may include the cell block SCB in which the plurality of memory cells illustrated in FIG. 1A are arranged, and the periphery region PR may include the periphery region PR including the main periphery region PRR and the subperiphery region SPR illustrated in FIG. 1A.

In some embodiments, the plurality of active regions ACT arranged in the memory cell region CR may be arranged to have a major axis in an oblique direction with respect to a first horizontal direction (X direction) and a second horizontal direction (Y direction).

A plurality of word lines WL may extend in parallel with each other in the first horizontal direction (X direction) across the plurality of active regions ACT. On the plurality of word lines WL, a plurality of bit lines BL may extend in parallel with each other in the second horizontal direction (Y direction) crossing the first horizontal direction (X direction). The plurality of bit lines BL may be connected to the plurality of active regions ACT via direct contacts DC.

In some embodiments, a plurality of buried contacts BC may be formed between two adjacent bit lines BL among the plurality of bit lines BL. In some embodiments, the plurality of buried contacts BC may be arranged in a line in each of the first horizontal direction (X direction) and the second horizontal direction (Y direction).

A plurality of landing pads LP may be respectively formed on the plurality of buried contacts BC. The plurality of landing pads LP may be arranged to at least partially overlap the plurality of buried contacts BC. In some embodiments, the plurality of landing pads LP may extend to an upper portion of any one bit line BL of two adjacent bit lines BL.

A plurality of storage nodes SN may be respectively formed on the plurality of landing pads LP. The plurality of storage nodes SN may be formed on the plurality of bit lines BL. Each of the plurality of storage nodes SN may include a lower electrode of each of a plurality of capacitors. The storage node SN may be connected to the active region ACT via the landing pad LP and the buried contact BC.

A plurality of gate line patterns GLP may be arranged on the logic active region ACTP in the periphery region PR. Although FIG. 1B illustrates that the plurality of gate line patterns GLP extend in parallel with each other in the first horizontal direction (X direction) on the logic active region ACTP and generally have a uniform width in the second horizontal direction (Y direction), the embodiment is not limited thereto. For example, each of the plurality of gate line patterns GLP may have a different width, have a curvature, or extend in a different direction.

In FIG. 1B, components except for the plurality of logic active regions ACTP and the plurality of gate line patterns GLP in the periphery region PR are omitted for convenience of illustration. In addition, although FIG. 1B illustrates that the plurality of gate line patterns GLPs are arranged only on the plurality of logic active regions ACTP, the embodiment is not limited thereto. For example, at least some of the plurality of gate line patterns GLP may extend outside the logic active region ACTP.

The plurality of gate line patterns GLP may be formed at the same level as the plurality of bit lines BL. In some embodiments, the plurality of gate line patterns GLP and the plurality of bit lines BL may include the same material, or at least some of the plurality of gate line patterns GLP and the plurality of bit lines BL may include the same material. For example, a process of forming all or portions of the plurality of gate line patterns GLP and a process of forming all or portions of the plurality of bit lines BL may include the same process.

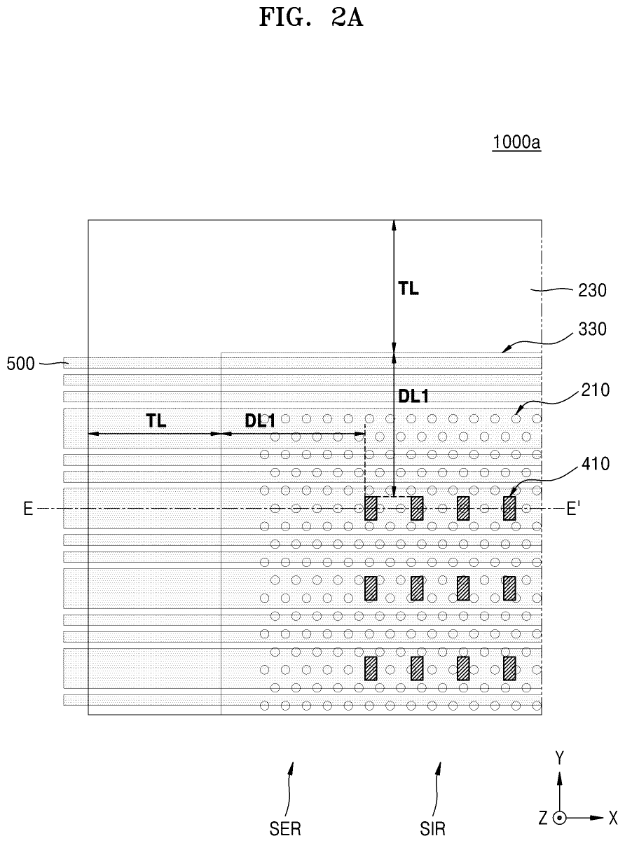

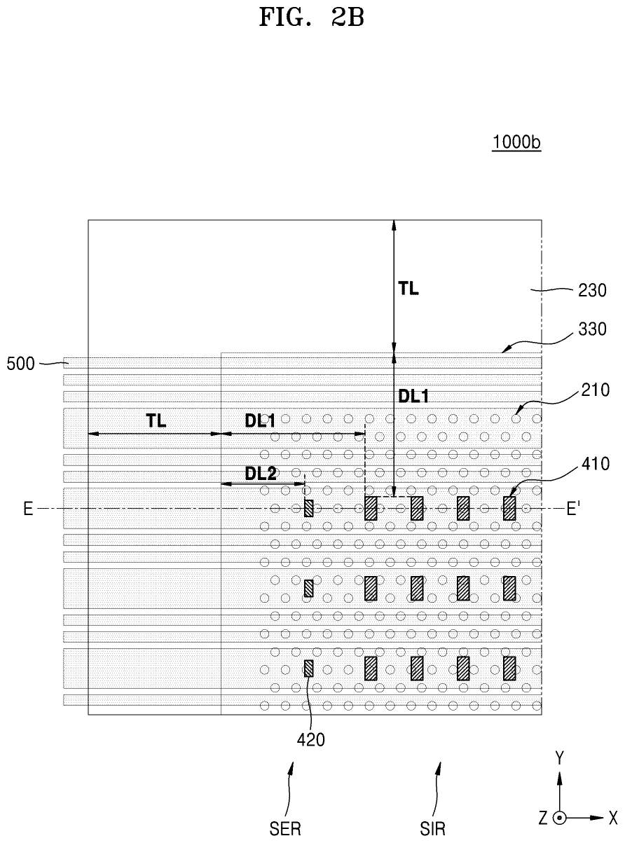

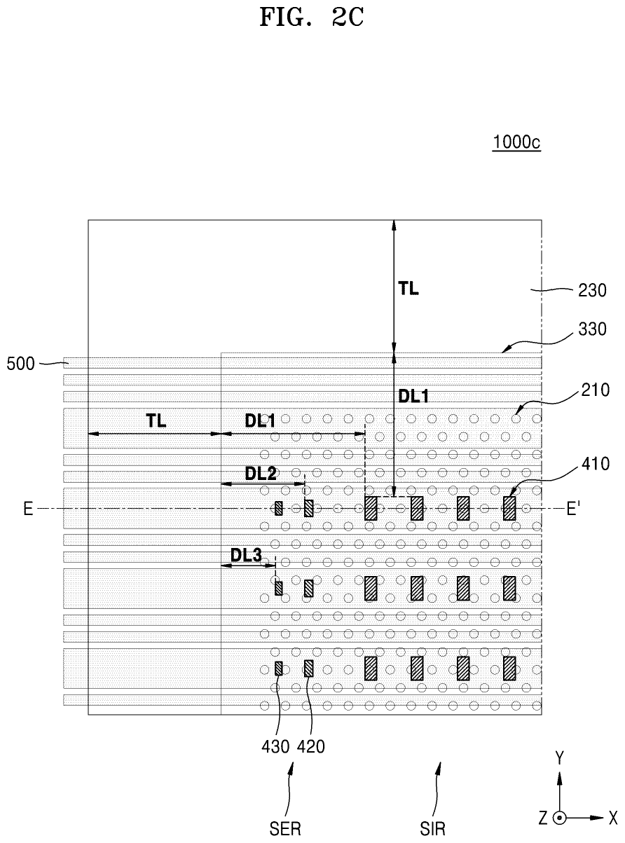

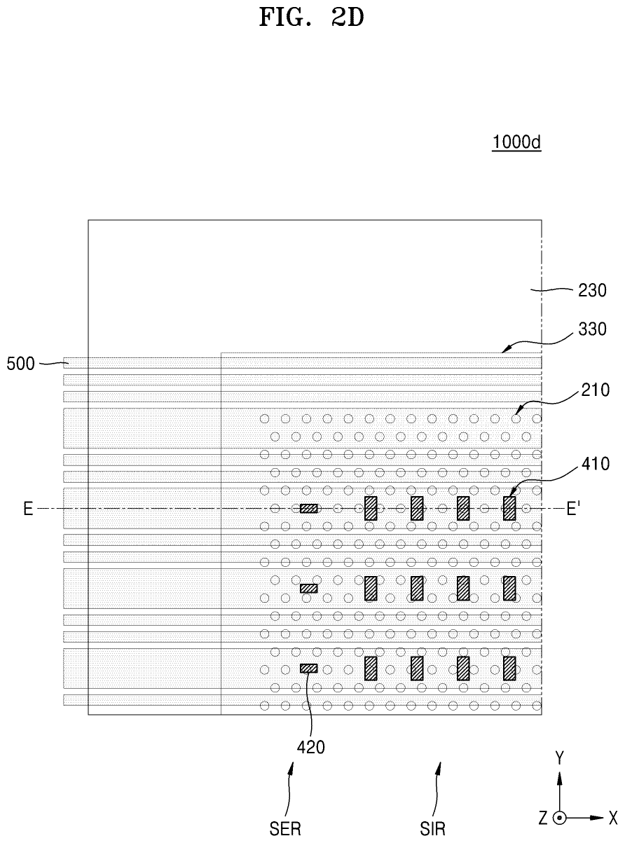

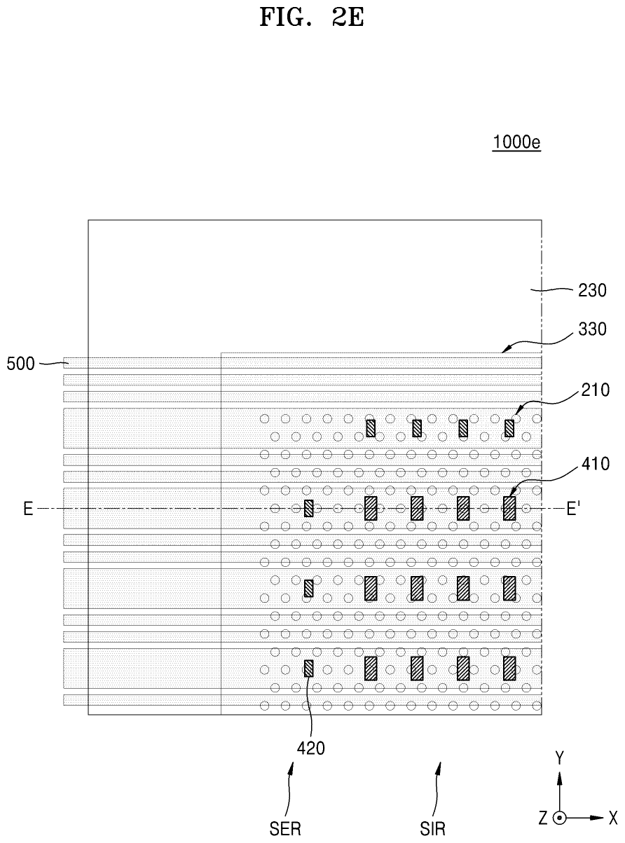

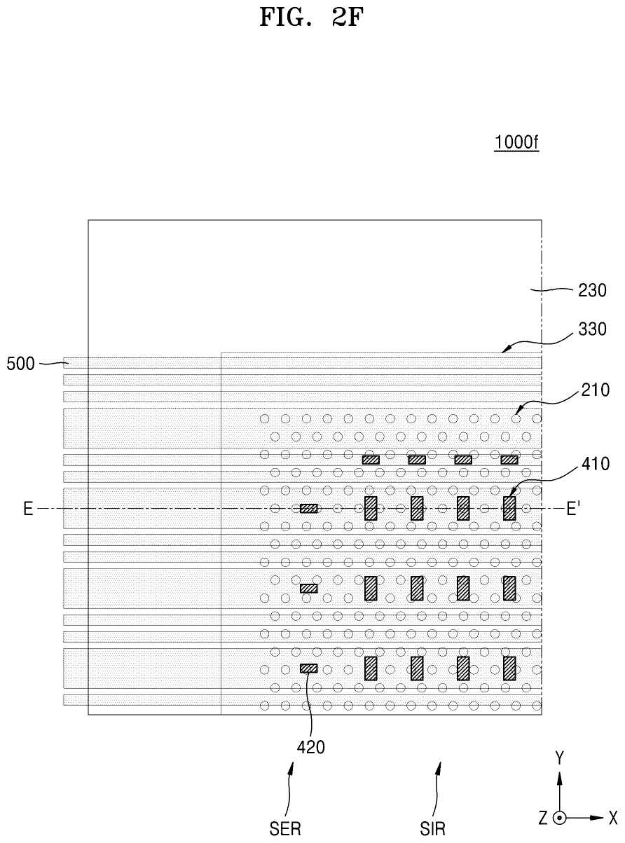

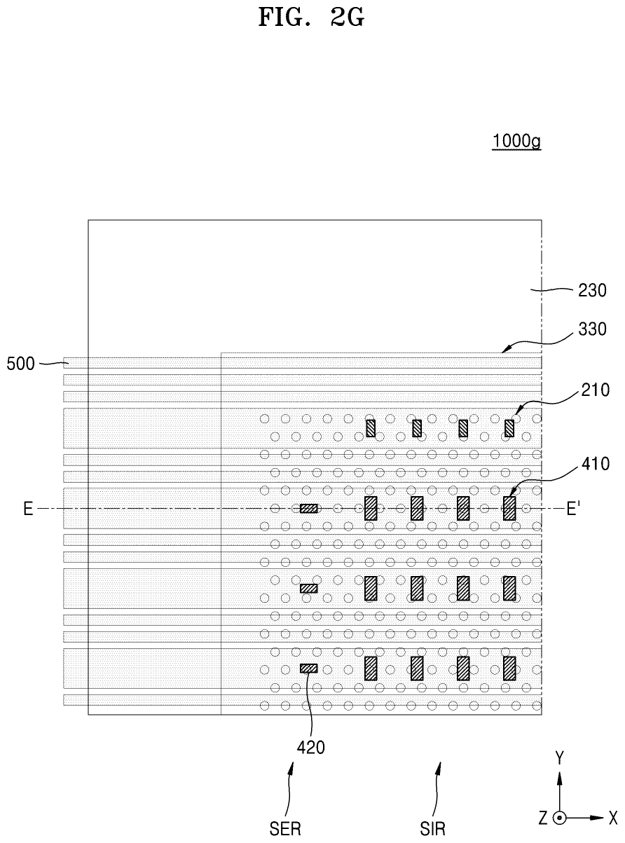

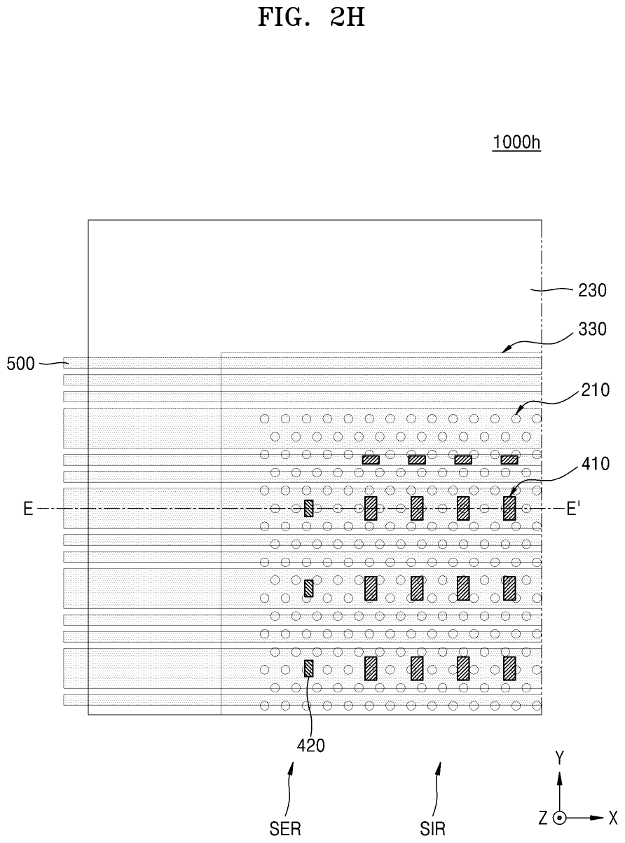

FIGS. 2A through 2H are plan layouts of semiconductor memory devices 1000a through 1000h according to embodiments. FIGS. 2A through 2H are plan layouts corresponding to portion II in FIG. 1A.

Referring to FIG. 2A, the semiconductor memory device 1000a may include a plurality of lower electrodes 210, an upper support pattern 330, an upper electrode 230, a plurality of first wiring contact plugs 410, and a plurality of wiring lines 500.

The plurality of lower electrodes 210 may be arranged in a honeycomb shape in a zigzag manner with respect to the first horizontal direction (X direction) or the second horizontal direction (Y direction) orthogonal to the first horizontal direction (X direction), but the embodiment is not limited thereto. In some embodiments, the plurality of lower electrodes 210 may be arranged in a line matrix shape in each of the first horizontal direction (X direction) and the second horizontal direction (Y direction). The plurality of lower electrodes 210 may include polysilicon doped with impurities, a metal, such as tungsten and copper, or a conductive metal compound such as titanium nitride. Each of the plurality of lower electrodes 210 may have a column shape with a filled inner portion thereof, that is, a pillar shape having a circular horizontal cross-section, but is not limited thereto. In some embodiments, each of the plurality of lower electrodes 210 may have a cylinder shape with a closed lower portion thereof.

The upper support pattern 330 may contact sidewalls of the plurality of lower electrodes 210 to support the plurality of lower electrodes 210. In a plan view, the plurality of lower electrodes 210 may be apart from an edge of the upper support pattern 330 and may be arranged inside the upper support pattern 330. The upper support pattern 330 may be in contact with upper end sidewalls of the plurality of lower electrodes 210. In some embodiments, the upper support pattern 330 may be in contact with uppermost end sidewalls of the plurality of lower electrodes 210. For example, an upper surface of a portion of the upper support pattern 330 in contact with the sidewall of any one lower electrode 210 among the plurality of lower electrodes 210, and an upper surface of any one lower electrode 210 may be at the same vertical level. The upper support pattern 330 may include any one material of silicon nitride (SiN), silicon carbon nitride (SiCN), N-rich SiN, or Si-rich SiN, but is not limited thereto.

The upper electrode 230 may cover the plurality of lower electrodes 210 and the upper support pattern 330. A capacitor dielectric layer (220 in FIGS. 11A through 11E) may be arranged between the plurality of lower electrodes 210 and the upper support pattern 330, and the upper electrode 230. The upper electrode 230 may have a stacked structure having one layer or at least two of a doped semiconductor material layer, a main electrode layer, and an interface layer. The doped semiconductor material may include at least one of, for example, doped polysilicon and doped polycrystalline silicon germanium (SiGe). The main electrode layer may include a metal material. The main electrode layer may include, for example, W, Ru, RuO, Pt, PtO, Ir, IrO, SrRuO (SRO), (Ba,Sr)RuO (BSRO), CaRuO (CRO), BaRuO, La(Sr,Co)O, etc. In some embodiments, the main electrode layer may include W. The interface layer may include at least one of metal oxide, metal nitride, metal carbide, and metal silicide.

In a plan view, the upper support pattern 330 may be apart from the edge of the upper electrode 230 and may be arranged inside the upper electrode 230. In other words, in a plan view, the edge of the upper support pattern 330 is apart from the edge of the upper electrode 230 and may be arranged inside the upper electrode 230. For example, a horizontal width and an area of the upper electrode 230 may be greater than a horizontal width and an area of the upper support pattern 330, respectively, and all portion of the upper support pattern 330 may overlap within the upper electrode 230 in the vertical direction (Z direction). In a plan view, the edge of the upper electrode 230 and the edge of the upper support pattern 330 may be apart from each other by a side surface thickness TL. The side surface thickness TL may be a thickness in the horizontal direction of a portion of the upper electrode 230 covering the side surface of the upper support pattern 330. The side surface thickness TL may be less than about 300 nm. For example, the side surface thickness TL may be about 230 nm to about 270 nm.

As used herein, the term “about” is relative to the actual value stated, as will be appreciated by those of skill in the art, and allows for approximations, inaccuracies and limits of measurement under the relevant circumstances. In one or more aspects, the terms “about,” “substantially,” and “approximately” may provide an industry-accepted tolerance for their corresponding terms and/or relativity between items, such as a tolerance of from less than one percent to 10 percent of the actual value stated, and other suitable tolerances.

The plurality of wiring lines 500 may be arranged on the upper electrode 230. The plurality of wiring lines 500 may be apart from the upper electrode 230 in a vertical direction (Z direction). In some embodiments, the plurality of wiring lines 500 may each extend in the first horizontal direction (X direction) and may be apart from each other in the second horizontal direction (Y direction). At least one of the plurality of wiring lines 500 may be electrically connected to the upper electrode 230 to provide power to the upper electrode 230. In some embodiments, some of the plurality of wiring lines 500 and the other wiring lines 500 may have different horizontal widths from each other in the second horizontal direction (Y direction). In some embodiments, at least some wiring lines 500 having a relatively large horizontal width in the second horizontal direction (Y direction) among the plurality of wiring lines 500 may be electrically connected to the upper electrode 230 to provide power to the upper electrode 230, but are not limited thereto. For example, each of at least one wiring line 500 having a relatively large horizontal width and at least one other wiring line 500 having a relatively small horizontal width among the plurality of wiring lines 500 may be electrically connected to the upper electrode 230 to provide power to the upper electrode 230.

Each of the plurality of first wiring contact plugs 410 may be arranged between the wiring line 500 having a relatively large horizontal width among the plurality of wiring lines 500 and the upper electrode 230, and may electrically connect the wiring line 500 having a relatively large horizontal width among the plurality of wiring lines 500 to the upper electrode 230. In some embodiments, each of the plurality of first wiring contact plugs 410 may have a rectangular flat surface shape, or a flat surface shape similar to a rectangle, for example, a rectangular flat surface shape with rounded corners thereof. In some embodiments, a major axis direction on the flat surface shape of each of the plurality of first wiring contact plugs 410 may include a direction orthogonal to an extension direction of the wiring line 500 to which each of the plurality of first wiring contact plugs 410 is connected. For example, the major axis direction on the flat surface shape of each of the plurality of first wiring contact plugs 410 may include the second horizontal direction (Y direction) orthogonal to the first horizontal direction (X direction) that is the extension direction of the wiring line 500 to which each of the plurality of first wiring contact plugs 410 is connected. For example, a horizontal width in the long axis direction of each of the plurality of first wiring contact plugs 410 may be about 50 nm to about 60 nm, and the horizontal width in a minor axis direction thereof may be about 30 nm to about 40 nm.

In a plan view, the plurality of first wiring contact plugs 410 may be apart from the edge of the upper support pattern 330 to the inside of the upper support pattern 330 by at least a first horizontal separation distance DL1. In other words, in a plan view, the first wiring contact plug 410 closest to the edge of the upper support pattern 330 among the plurality of first wiring contact plugs 410 may be apart from the edge of the upper support pattern 330 by the first horizontal separation distance DL1. The first horizontal separation distance DL1 may be greater than the side surface thickness TL. In a plan view, each of the plurality of first wiring contact plugs 410 may be apart from the edge of the upper support pattern 330 by a separation distance greater than the side surface thickness TL. For example, the first horizontal separation distance DL1 may be about 300 nm. In a plan view, a region from an edge of an upper support pattern 330 to the first horizontal separation distance DL1 may be referred to as an edge support region SER, and a region from the edge of the upper support pattern 330 to a distance greater than the first horizontal separation distance DL1 may be referred to as an inner support region SIR. The plurality of first wiring contact plugs 410 may be arranged in the inner support region SIR, but may not be arranged in the edge support region SER.

Referring to FIG. 2B, the semiconductor memory device 1000b may include the plurality of lower electrodes 210, the upper support pattern 330, the upper electrode 230, the plurality of first wiring contact plugs 410, a plurality of second wiring contact plugs 420, and the plurality of wiring lines 500.

The upper support pattern 330 may be in contact with the sidewalls of the plurality of lower electrodes 210 to support the plurality of lower electrodes 210. The upper electrode 230 may cover the plurality of lower electrodes 210 and the upper support pattern 330. In a plan view, the upper support pattern 330 may be apart from the edge of the upper electrode 230 and may be arranged inside the upper electrode 230. In a plan view, the edge of the upper electrode 230 and the edge of the upper support pattern 330 may be apart from each other by the side surface thickness TL. The plurality of wiring lines 500 may be arranged on the upper electrode 230. The plurality of wiring lines 500 may be apart from the upper electrode 230 in the vertical direction (Z direction).

Each of the plurality of first wiring contact plugs 410 and the plurality of second wiring contact plugs 420 may be arranged between the wiring line 500 having a relatively large horizontal width among the plurality of wiring lines 500 and the upper electrode 230, and may electrically connect the wiring line 500 having a relatively large horizontal width among the plurality of wiring lines 500 to the upper electrode 230.

In some embodiments, each of the plurality of first wiring contact plugs 410 and the plurality of second wiring contact plugs 420 may have a rectangular flat surface shape, or a flat surface shape similar to a rectangle, for example, a rectangular flat surface shape with rounded corners thereof. In some embodiments, the major axis direction in the flat surface shape of each of the plurality of first wiring contact plugs 410 and the plurality of second wiring contact plugs 420 may include a direction orthogonal to the extension direction of the wiring line 500 to which each of the plurality of first wiring contact plugs 410 and the plurality of second wiring contact plugs 420 is connected. For example, the major axis direction in the flat surface shape of each of the plurality of first wiring contact plugs 410 and the plurality of second wiring contact plugs 420 may include the second horizontal direction (Y direction) orthogonal to the first horizontal direction (X direction) that is the extension direction of the wiring line 500 to which each of the plurality of first wiring contact plugs 410 and the plurality of second wiring contact plugs 420 is connected.

At the same vertical level, a horizontal area of each of the plurality of second wiring contact plugs 420 may be about 60% to about 80% of a horizontal area of each of the plurality of first wiring contact plugs 410. The horizontal width in the major axis direction of each of the plurality of second wiring contact plugs 420 may be less than the horizontal width in the major axis direction of each of the plurality of first wiring contact plugs 410. The horizontal width in the minor axis direction of each of the plurality of second wiring contact plugs 420 may be less than the horizontal width in the minor axis direction of each of the plurality of first wiring contact plugs 410. The horizontal width in the major axis direction of each of the plurality of second wiring contact plugs 420 may be about 80% to 90% of the horizontal width in the major axis direction of each of the plurality of first wiring contact plugs 410, and the horizontal width in the minor axis direction of each of the plurality of second wiring contact plugs 420 may be about 80% to 90% of the horizontal width in the minor axis direction of each of the plurality of first wiring contact plugs 410. For example, the horizontal width in the long axis direction of each of the plurality of first wiring contact plugs 410 may be about 50 nm to about 60 nm, and the horizontal width in the minor axis direction thereof may be about 30 nm to about 40 nm. For example, the horizontal width in the long axis direction of each of the plurality of second wiring contact plugs 420 may be about 40 nm to about 55 nm, and the horizontal width in the minor axis direction thereof may be about 25 nm to about 35 nm.

In a plan view, the plurality of first wiring contact plugs 410 may be apart from the edge of the upper support pattern 330 to the inside of the upper support pattern 330 by at least the first horizontal separation distance DL1. In a plan view, each of the plurality of second wiring contact plugs 420 may be apart from the edge of the upper support pattern 330 to the inside of the upper support pattern 330 by a second horizontal separation distance DL2. The second horizontal separation distance DL2 may be less than the first horizontal separation distance DL1. The first horizontal separation distance DL1 may be greater than the side surface thickness TL. In some embodiments, the second horizontal separation distance DL2 may less than the side surface thickness TL. For example, the first horizontal separation distance DL1 may be about 300 nm, and the second horizontal separation distance DL2 may be about 180 nm to about 240 nm.

In some embodiments, the plurality of second wiring contact plugs 420 may be arranged on one side in the first horizontal direction (X direction), that is an extension direction of the wiring line 500, from the plurality of first wiring contact plugs 410, and may be arranged closer to the edge of the upper support pattern 330 than the plurality of first wiring contact plugs 410.

The plurality of first wiring contact plugs 410 may be arranged in the inner support region SIR, but may not be arranged in the edge support region SER, and the plurality of second wiring contact plugs 420 may be arranged in the edge support region SER, but may not be arranged in the inner support region SIR.

Referring to FIG. 2C, the semiconductor memory device 1000c may include the plurality of lower electrodes 210, the upper support pattern 330, the upper electrode 230, the plurality of first wiring contact plugs 410, a plurality of third wiring contact plugs 430, and the plurality of wiring lines 500.

The upper support pattern 330 may be in contact with the sidewalls of the plurality of lower electrodes 210 to support the plurality of lower electrodes 210. The upper electrode 230 may cover the plurality of lower electrodes 210 and the upper support pattern 330. In a plan view, the upper support pattern 330 may be apart from the edge of the upper electrode 230 and may be arranged inside the upper electrode 230. In a plan view, the edge of the upper electrode 230 and the edge of the upper support pattern 330 may be apart from each other by the side surface thickness TL. The plurality of wiring lines 500 may be arranged on the upper electrode 230. The plurality of wiring lines 500 may be apart from the upper electrode 230 in the vertical direction (Z direction).

The plurality of first wiring contact plugs 410, the plurality of second wiring contact plugs 420, and the plurality of third wiring contact plugs 430 may be arranged between at least some wiring lines 500 among the plurality of wiring lines 500 and the upper electrode 230, and may electrically connect the at least some wiring lines 500 among the plurality of wiring lines 500 to the upper electrode 230. In some embodiments, each of the plurality of first wiring contact plugs 410, the plurality of second wiring contact plugs 420, and the plurality of third wiring contact plugs 430 may have a rectangular flat surface shape, or a flat surface shape similar to a rectangle, for example a flat surface shape with rounded corners thereof. In some embodiments, in a plan view, the major axis direction in the flat surface shape of each of the plurality of first wiring contact plugs 410, the plurality of second wiring contact plugs 420, and the plurality of third wiring contact plugs 430 may include a direction orthogonal to the extension direction of the wiring line 500 to which each of the plurality of first wiring contact plugs 410, the plurality of second wiring contact plugs 420, and the plurality of third wiring contact plugs 430 is connected. For example, in a plan view, the major axis direction of each of the plurality of first wiring contact plugs 410, the plurality of second wiring contact plugs 420, and the plurality of third wiring contact plugs 430 may include the second horizontal direction (Y direction) orthogonal to the first horizontal direction (X direction), that is the extension direction of the wiring line 500 to which each of the plurality of first wiring contact plugs 410, the plurality of second wiring contact plugs 420, and the plurality of third wiring contact plugs 430 is connected.

At the same vertical level, a horizontal area of each of the plurality of third wiring contact plugs 430 may be about 60% to about 80% of a horizontal area of each of the plurality of second wiring contact plugs 420, and the horizontal area of each of the plurality of second wiring contact plugs 420 may be about 60% to about 80% of the horizontal area of each of the plurality of first wiring contact plugs 410. The horizontal width in the major axis direction of each of the plurality of third wiring contact plugs 430 may be less than the horizontal width in the major axis direction of each of the plurality of first wiring contact plugs 410, and the horizontal width in the major axis direction of each of the plurality of second wiring contact plugs 420 may be less than the horizontal width in the major axis direction of each of the plurality of first wiring contact plugs 410. The horizontal width in the minor axis direction of each of the plurality of third wiring contact plugs 430 may be less than the horizontal width in the minor axis direction of each of the plurality of first wiring contact plugs 410, and the horizontal width in the minor axis direction of each of the plurality of second wiring contact plugs 420 may be less than the horizontal width in the minor axis direction of each of the plurality of first wiring contact plugs 410. The horizontal width in the major axis direction of each of the plurality of third wiring contact plugs 430 may be about 80% to about 90% of the horizontal width in the major axis direction of each of the plurality of second wiring contact plugs 420, and the horizontal width in the minor axis direction of each of the plurality of third wiring contact plugs 430 may be about 80% to about 90% of the horizontal width in the minor axis direction of each of the plurality of second wiring contact plugs 420. The horizontal width in the major axis direction of each of the plurality of second wiring contact plugs 420 may be about 80% to about 90% of the horizontal width in the major axis direction of each of the plurality of first wiring contact plugs 410, and the horizontal width in the minor axis direction of each of the plurality of second wiring contact plugs 420 may be about 80% to about 90% of the horizontal width in the minor axis direction of each of the plurality of first wiring contact plugs 410.

In a plan view, the plurality of first wiring contact plugs 410 may be apart from the edge of the upper support pattern 330 to the inside of the upper support pattern 330 by at least the first horizontal separation distance DL1. In a plan view, each of the plurality of second wiring contact plugs 420 may be apart from the edge of the upper support pattern 330 to the inside of the upper support pattern 330 by the second horizontal separation distance DL2. In a plan view, each of the plurality of third wiring contact plugs 430 may be apart from the edge of the upper support pattern 330 to the inside of the upper support pattern 330 by a third horizontal separation distance DL3. The third horizontal separation distance DL3 may be less than the second horizontal separation distance DL2, and the second horizontal separation distance DL2 may be less than the first horizontal separation distance DL1. The first horizontal separation distance DL1 may be greater than the side surface thickness TL. In some embodiments, each of the second horizontal separation distance DL2 and the third horizontal separation distance DL3 may be less than the side surface thickness TL. For example, the first horizontal separation distance DL1 may be about 300 nm, the second horizontal separation distance DL2 may be about 180 nm to about 240 nm, and the third horizontal separation distance DL3 may be about 60 nm to about 200 nm.

In some embodiments, the plurality of second wiring contact plugs 420 may be arranged on one side in the first horizontal direction (X direction), that is the extension direction of the wiring line 500, from the plurality of first wiring contact plugs 410, and may be arranged closer to the edge of the upper support pattern 330 than the plurality of first wiring contact plugs 410. The plurality of third wiring contact plugs 430 may be arranged on one side in the first horizontal direction (X direction), that is the extension direction of the wiring line 500, from the plurality of first wiring contact plugs 410 and the plurality of second wiring contact plugs 420, and may be arranged closer to the edge of the upper support pattern 330 than the plurality of first wiring contact plugs 410 and the plurality of second wiring contact plugs 420.

The plurality of first wiring contact plugs 410 may be arranged in the inner support region SIR, but may not be arranged in the edge support region SER, and the plurality of second wiring contact plugs 420 and the plurality of third wiring contact plugs 430 may be arranged in the edge support region SER, but may not be arranged in the inner support region SIR.

Referring to FIG. 2D, the semiconductor memory device 1000d may include the plurality of lower electrodes 210, the upper support pattern 330, the upper electrode 230, the plurality of first wiring contact plugs 410, the plurality of second wiring contact plugs 420, and the plurality of wiring lines 500.

The upper support pattern 330 may be in contact with the sidewalls of the plurality of lower electrodes 210 to support the plurality of lower electrodes 210. The upper electrode 230 may cover the plurality of lower electrodes 210 and the upper support pattern 330. In a plan view, the upper support pattern 330 may be apart from the edge of the upper electrode 230 and may be arranged inside the upper electrode 230. The plurality of wiring lines 500 may be apart from the upper electrode 230 in the vertical direction (Z direction).

The plurality of first wiring contact plugs 410 and the plurality of second wiring contact plugs 420 may be arranged between at least some wiring lines 500 among the plurality of wiring lines 500 and the upper electrode 230, and may electrically connect the at least some wiring lines 500 among the plurality of wiring lines 500 to the upper electrode 230. In some embodiments, the major axis direction on the flat surface shape of the plurality of first wiring contact plugs 410 may include a direction orthogonal to the extension direction of the wiring line 500, to which each of the plurality of first wiring contact plugs 410 is connected, and the major axis direction on the flat surface shape of the plurality of second wiring contact plugs 420 may include the extension direction of the wiring line 500 to which each of the plurality of second wiring contact plugs 420 is connected. For example, the major axis direction on the flat surface shape of each of the plurality of first wiring contact plugs 410 may include the second horizontal direction (Y direction) orthogonal to the first horizontal direction (X direction), that is the extension direction of the wiring line 500, to which each of the plurality of first wiring contact plugs 410 is connected, and the major axis direction in the flat surface shape of each of the plurality of second wiring contact plugs 420 may include the first horizontal direction (X direction), that is the extension direction of the wiring line 500 to which each of the plurality of second wiring contact plugs 420 is connected.

Referring to FIG. 2E, the semiconductor memory device 1000e may include the plurality of lower electrodes 210, the upper support pattern 330, the upper electrode 230, the plurality of first wiring contact plugs 410, the plurality of second wiring contact plugs 420, and the plurality of wiring lines 500.

The upper support pattern 330 may be in contact with the sidewalls of the plurality of lower electrodes 210 to support the plurality of lower electrodes 210. The upper electrode 230 may cover the plurality of lower electrodes 210 and the upper support pattern 330. In a plan view, the upper support pattern 330 may be apart from the edge of the upper electrode 230 and may be arranged inside the upper electrode 230. The plurality of wiring lines 500 may be apart from the upper electrode 230 in the vertical direction (Z direction).

The plurality of first wiring contact plugs 410 and the plurality of second wiring contact plugs 420 may be arranged between at least some wiring lines 500 among the plurality of wiring lines 500 and the upper electrode 230, and may electrically connect the at least some wiring lines 500 among the plurality of wiring lines 500 to the upper electrode 230. In some embodiments, the major axis direction on the flat surface shape of each of the plurality of first wiring contact plugs 410 and the plurality of second wiring contact plugs 420 may include a direction orthogonal to the extension direction of the wiring line 500 to which each of the plurality of first wiring contact plugs 410 and the plurality of second wiring contact plugs 420 is connected. For example, the major axis direction on the flat surface shape of each of the plurality of first wiring contact plugs 410 and the plurality of second wiring contact plugs 420 may include the second horizontal direction (Y direction) orthogonal to the first horizontal direction (X direction), that is the extension direction of the wiring line 500 to which each of the plurality of first wiring contact plugs 410 and the plurality of second wiring contact plugs 420 is connected.

In some embodiments, each of the plurality of second wiring contact plugs 420 may be arranged on one side in the first horizontal direction (X direction), that is an extension direction of the wiring line 500 from the plurality of first wiring contact plugs 410, or may be arranged on one side in the second horizontal direction (Y direction) orthogonal to the extension direction of the wiring line 500, and may be arranged closer to the edge of the upper support pattern 330 than the plurality of first wiring contact plugs 410.

Referring to FIG. 2F, the semiconductor memory device 1000f may include the plurality of lower electrodes 210, the upper support pattern 330, the upper electrode 230, the plurality of first wiring contact plugs 410, the plurality of second wiring contact plugs 420, and the plurality of wiring lines 500.

The upper support pattern 330 may be in contact with the sidewalls of the plurality of lower electrodes 210 to support the plurality of lower electrodes 210. The upper electrode 230 may cover the plurality of lower electrodes 210 and the upper support pattern 330. In a plan view, the upper support pattern 330 may be apart from the edge of the upper electrode 230 and may be arranged inside the upper electrode 230. The plurality of wiring lines 500 may be apart from the upper electrode 230 in the vertical direction (Z direction).

The plurality of first wiring contact plugs 410 and the plurality of second wiring contact plugs 420 may be arranged between at least some wiring lines 500 among the plurality of wiring lines 500 and the upper electrode 230, and may electrically connect the at least some wiring lines 500 among the plurality of wiring lines 500 to the upper electrode 230. In some embodiments, the major axis direction on the flat surface shape of each of the plurality of first wiring contact plugs 410 may include a direction orthogonal to the extension direction of the wiring line 500, to which each of the plurality of first wiring contact plugs 410 is connected, and the major axis direction in the flat surface shape of each of the plurality of second wiring contact plugs 420 may include the extension direction of the wiring line 500 to which each of the plurality of second wiring contact plugs 420 is connected. For example, the major axis direction on the flat surface shape of each of the plurality of first wiring contact plugs 410 may include the second horizontal direction (Y direction) orthogonal to the first horizontal direction (X direction), that is the extension direction of the wiring line 500, to which each of the plurality of first wiring contact plugs 410 is connected, and the major axis direction in the flat surface shape of each of the plurality of second wiring contact plugs 420 may include the first horizontal direction (X direction), that is the extension direction of the wiring line 500 to which each of the plurality of second wiring contact plugs 420 is connected.

In some embodiments, each of the plurality of second wiring contact plugs 420 may be arranged on one side in the first horizontal direction (X direction), that is an extension direction of the wiring line 500, from the plurality of first wiring contact plugs 410, or may be arranged on one side in the second horizontal direction (Y direction) orthogonal to the extension direction of the wiring line 500, and thus, may be arranged closer to the edge of the upper support pattern 330 than the plurality of first wiring contact plugs 410.

In some embodiments, the second wiring contact plug 420 arranged on one side of a plurality of second wiring contact plugs 420 in the first horizontal direction (X direction), that is the extension direction of the wiring line 500, may be arranged between the wiring line 500 having a relatively large horizontal width among the plurality of wiring lines 500 and the upper electrode 230, and the second wiring contact plug 420 arranged on one side of the plurality of first wiring contact plugs 410 in the second horizontal direction (Y direction) orthogonal to the extension direction of the wiring line 500 may be arranged between the wiring line 500 having a relatively small horizontal width among the plurality of wiring lines 500 and the upper electrode 230.

Referring to FIG. 2G, the semiconductor memory device 1000g may include the plurality of lower electrodes 210, the upper support pattern 330, the upper electrode 230, the plurality of first wiring contact plugs 410, the plurality of second wiring contact plugs 420, and the plurality of wiring lines 500.

The upper support pattern 330 may be in contact with the sidewalls of the plurality of lower electrodes 210 to support the plurality of lower electrodes 210. The upper electrode 230 may cover the plurality of lower electrodes 210 and the upper support pattern 330. In a plan view, the upper support pattern 330 may be apart from the edge of the upper electrode 230 and may be arranged inside the upper electrode 230. The plurality of wiring lines 500 may be apart from the upper electrode 230 in the vertical direction (Z direction).

The plurality of first wiring contact plugs 410 and the plurality of second wiring contact plugs 420 may be arranged between at least some wiring lines 500 among the plurality of wiring lines 500 and the upper electrode 230, and may electrically connect the at least some wiring lines 500 among the plurality of wiring lines 500 to the upper electrode 230.

In some embodiments, each of the plurality of second wiring contact plugs 420 may be arranged on one side in the first horizontal direction (X direction), that is an extension direction of the wiring line 500, from the plurality of first wiring contact plugs 410, or may be arranged on one side in the second horizontal direction (Y direction) orthogonal to the extension direction of the wiring line 500, and thus, may be arranged closer to the edge of the upper support pattern 330 than the plurality of first wiring contact plugs 410.

In some embodiments, the major axis direction on the flat surface shape of each of the plurality of first wiring contact plugs 410 may include a direction orthogonal to an extension direction of the wiring line 500 to which each of the plurality of first wiring contact plugs 410 is connected. The major axis direction on the flat surface shape of the second wiring contact plug 420 arranged on one side in the first horizontal direction (X direction), that is the extension direction of the wiring line 500, from the plurality of first wiring contact plugs 410 among the plurality of second wiring contact plugs 420 may include the first horizontal direction (X direction), that is the extension direction of the wiring line 500 to which the second wiring contact plug 420 is connected, and the major axis direction on the flat surface shape of the second wiring contact plug 420 arranged on one side in the second horizontal direction (Y direction) orthogonal to the extension direction of the wiring line 500 from the plurality of first wiring contact plugs 410 among the plurality of second wiring contact plugs 420 may include the second horizontal direction (Y direction) orthogonal to the extension direction of the wiring line 500 to which the second wiring contact plug 420 is connected.

Referring to FIG. 2H, the semiconductor memory device 1000h may include the plurality of lower electrodes 210, the upper support pattern 330, the upper electrode 230, the plurality of first wiring contact plugs 410, the plurality of second wiring contact plugs 420, and the plurality of wiring lines 500.

The upper support pattern 330 may be in contact with the sidewalls of the plurality of lower electrodes 210 to support the plurality of lower electrodes 210. The upper electrode 230 may cover the plurality of lower electrodes 210 and the upper support pattern 330. In a plan view, the upper support pattern 330 may be apart from the edge of the upper electrode 230 and may be arranged inside the upper electrode 230. The plurality of wiring lines 500 may be apart from the upper electrode 230 in the vertical direction (Z direction).

The plurality of first wiring contact plugs 410 and the plurality of second wiring contact plugs 420 may be arranged between at least some wiring lines 500 among the plurality of wiring lines 500 and the upper electrode 230, and may electrically connect the at least some wiring lines 500 among the plurality of wiring lines 500 to the upper electrode 230.

In some embodiments, each of the plurality of second wiring contact plugs 420 may be arranged on one side in the first horizontal direction (X direction), that is an extension direction of the wiring line 500, from the plurality of first wiring contact plugs 410, or may be arranged on one side in the second horizontal direction (Y direction) orthogonal to the extension direction of the wiring line 500, and thus, may be arranged closer to the edge of the upper support pattern 330 than the plurality of first wiring contact plugs 410.

In some embodiments, the second wiring contact plug 420 arranged on one side of a plurality of second wiring contact plugs 420 in the first horizontal direction (X direction), that is the extension direction of the wiring line 500, may be arranged between the wiring line 500 having a relatively large horizontal width among the plurality of wiring lines 500 and the upper electrode 230, and the second wiring contact plug 420 arranged on one side of the plurality of first wiring contact plugs 410 in the second horizontal direction (Y direction) orthogonal to the extension direction of the wiring line 500 may be arranged between the wiring line 500 having a relatively small horizontal width among the plurality of wiring lines 500 and the upper electrode 230.

In some embodiments, the major axis direction on the flat surface shape of each of the plurality of first wiring contact plugs 410 may include a direction orthogonal to the extension direction of the wiring line 500 to which each of the plurality of first wiring contact plugs 410 is connected. The major axis direction on the flat surface shape of the second wiring contact plug 420 arranged on one side in the first horizontal direction (X direction), that is the extension direction of the wiring line 500, from the plurality of first wiring contact plugs 410 among the plurality of second wiring contact plugs 420 may include the second horizontal direction (Y direction), that is orthogonal to the extension direction of the wiring line 500 to which the second wiring contact plug 420 is connected, and the major axis direction on the flat surface shape of the second wiring contact plug 420 arranged on one side in the second horizontal direction (Y direction) orthogonal to the extension direction of the wiring line 500 from the plurality of first wiring contact plugs 410 among the plurality of second wiring contact plugs 420 may include the first horizontal direction (X direction) that is the extension direction of the wiring line 500 to which the second wiring contact plug 420 is connected.

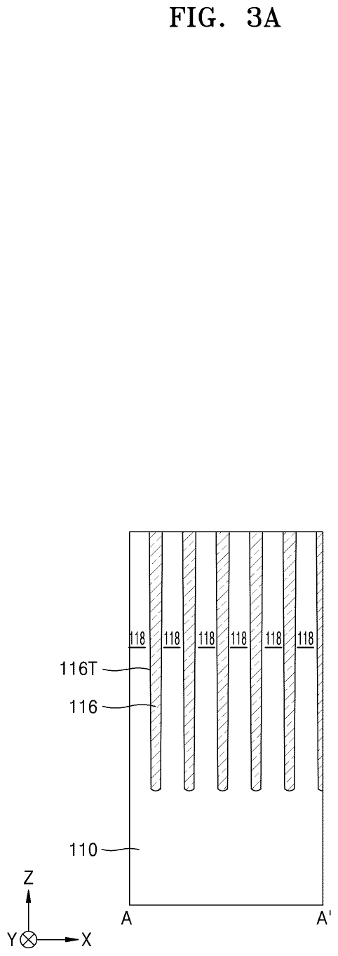

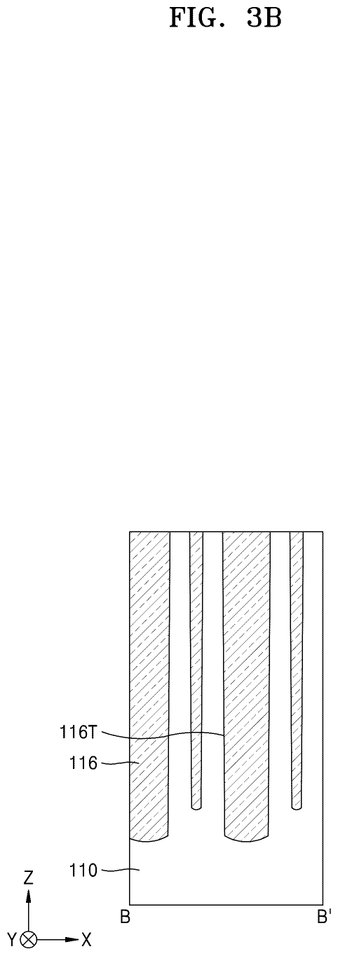

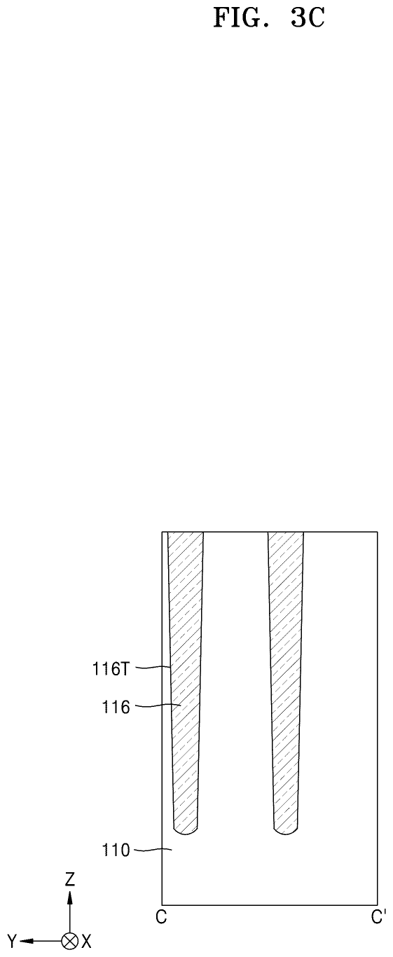

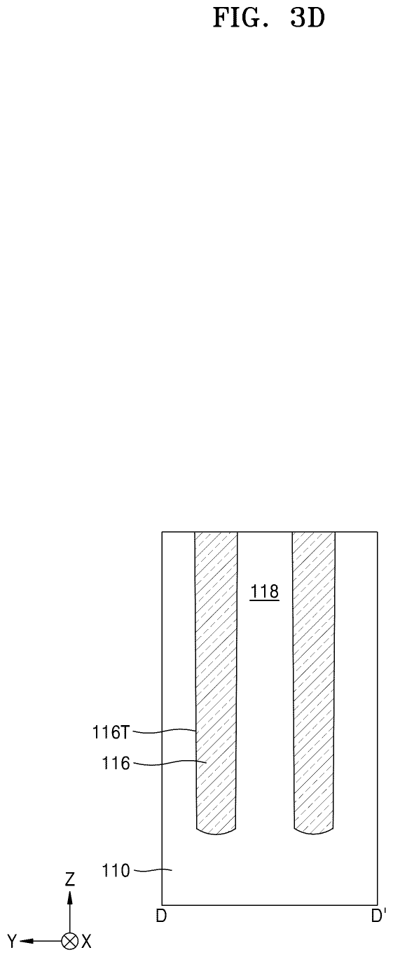

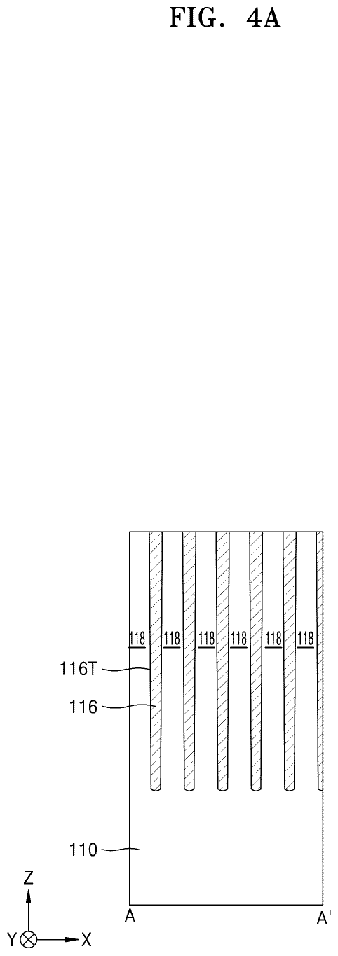

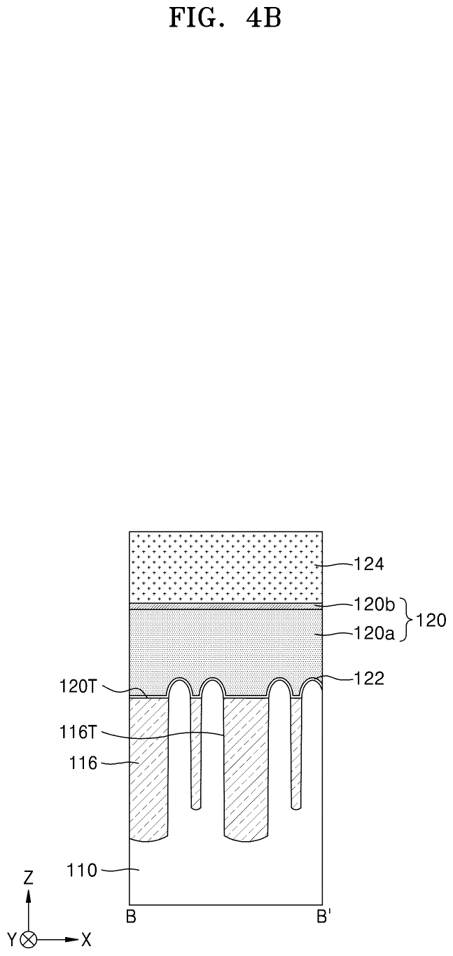

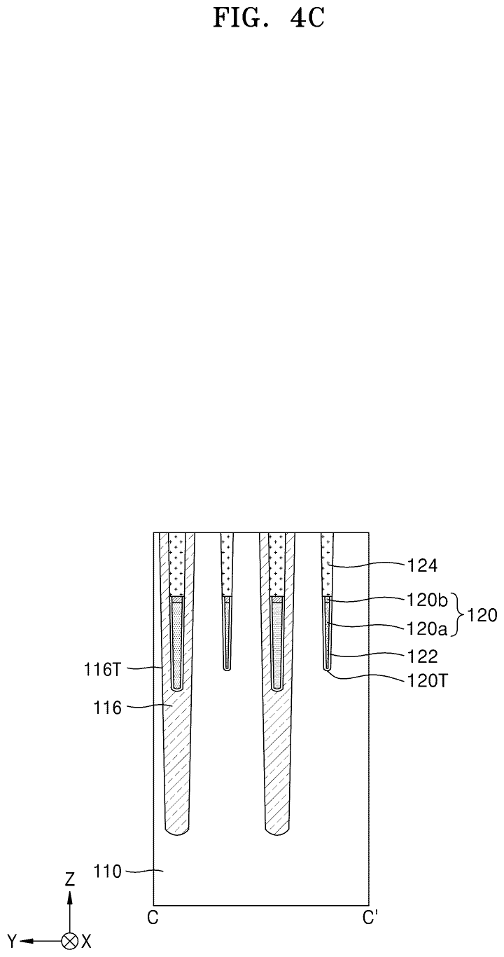

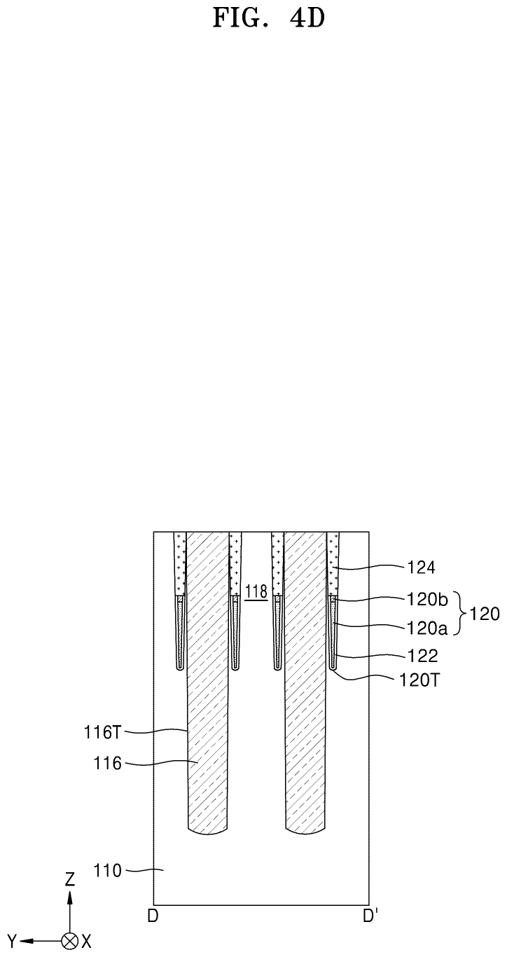

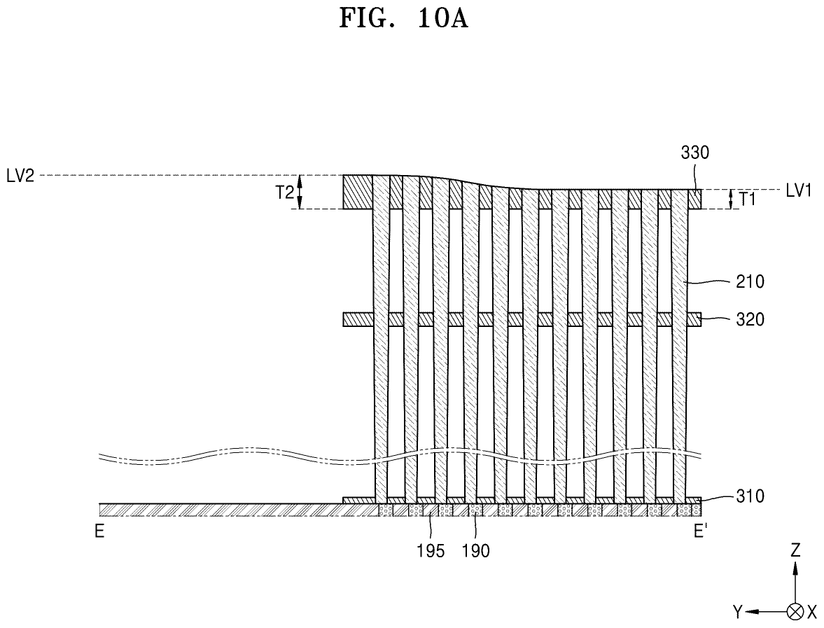

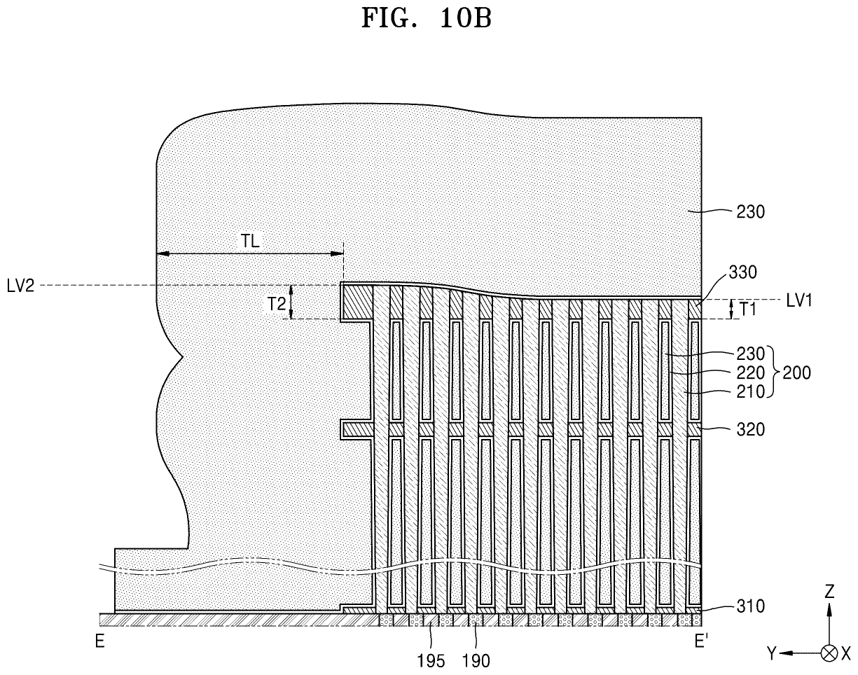

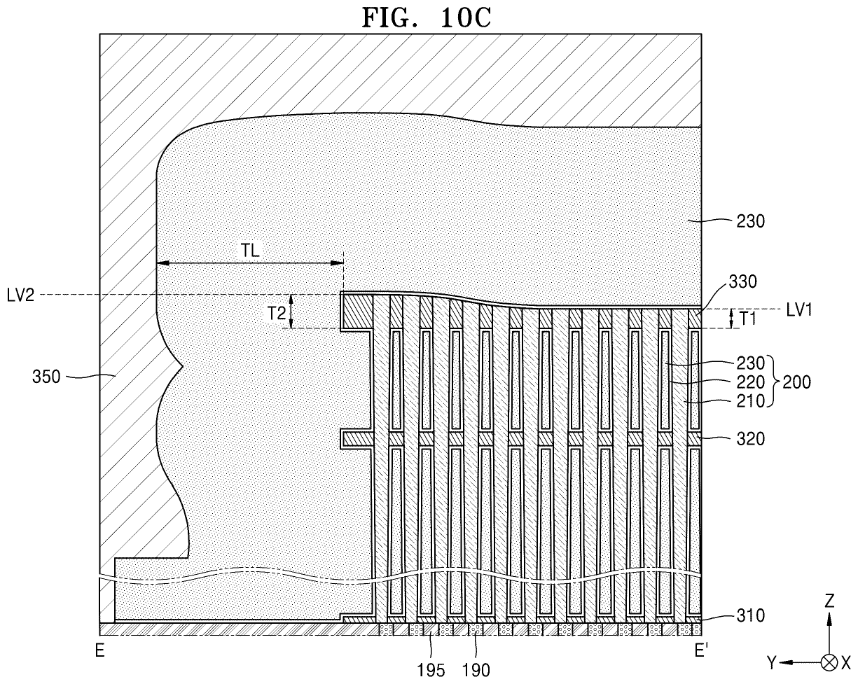

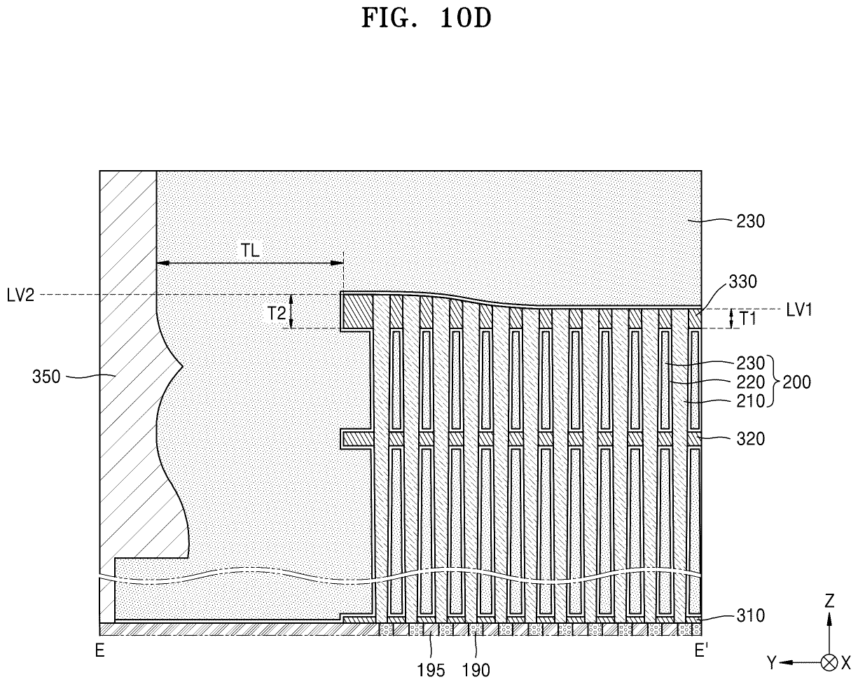

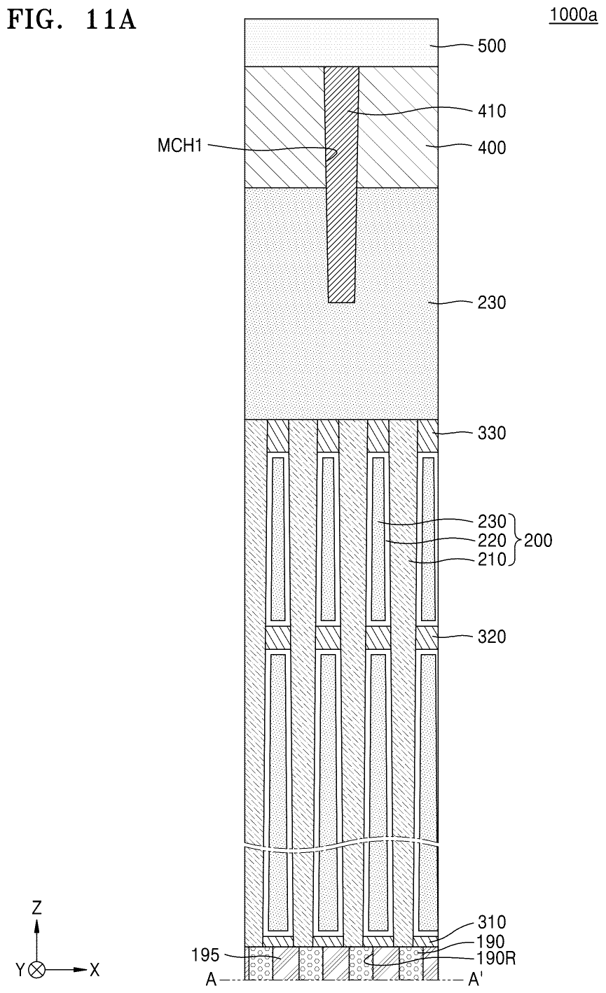

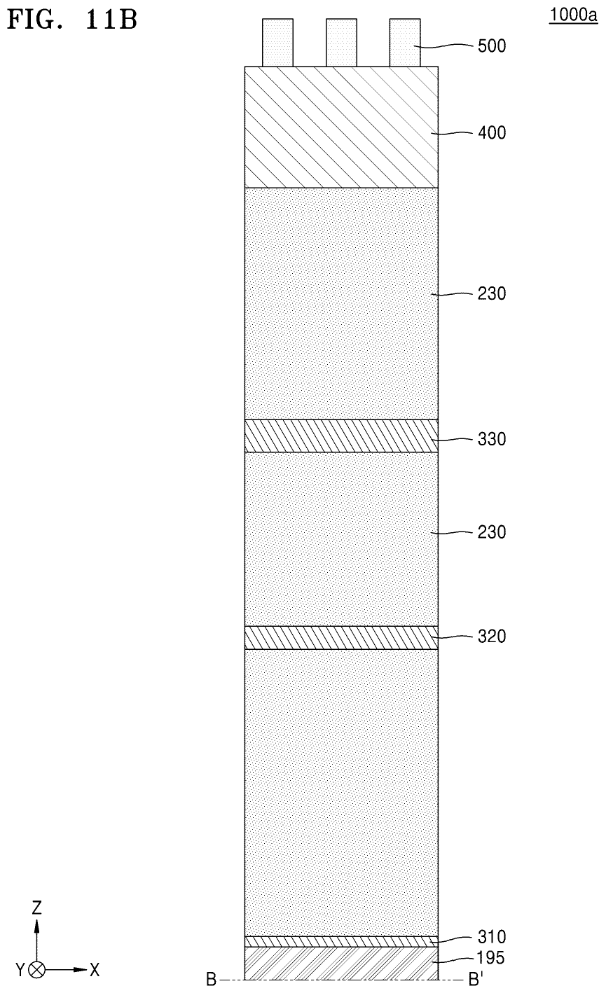

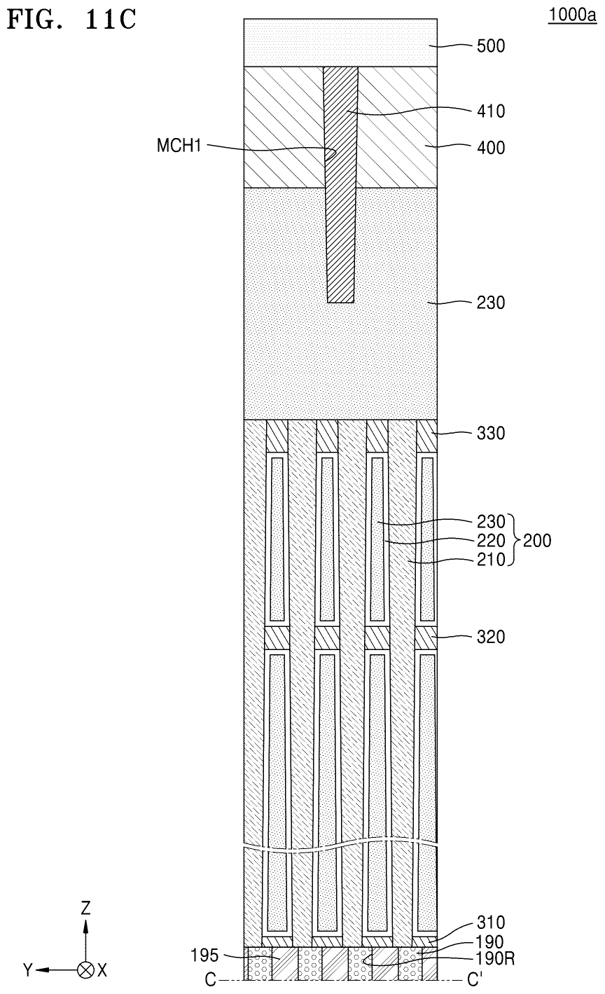

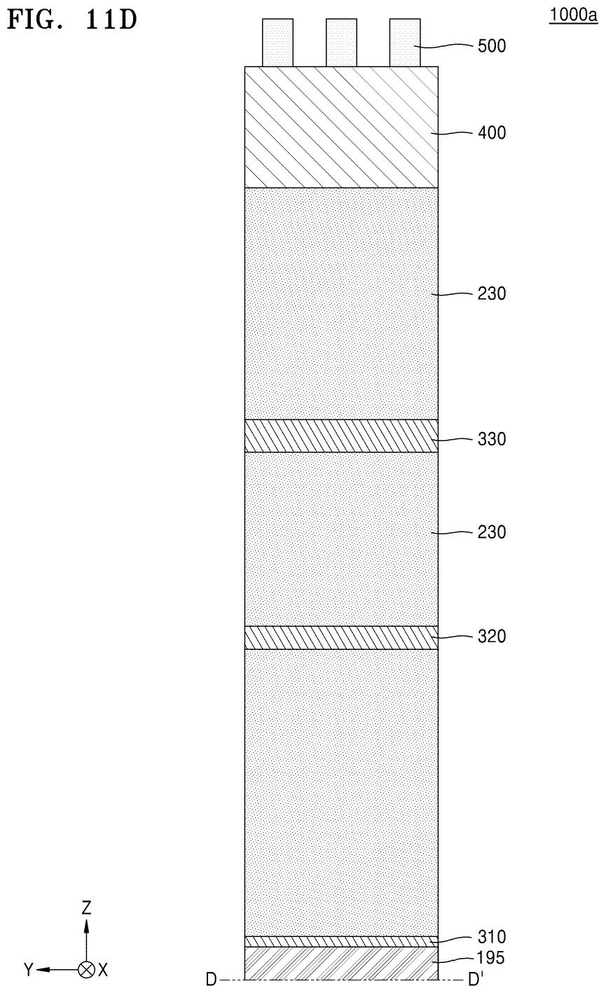

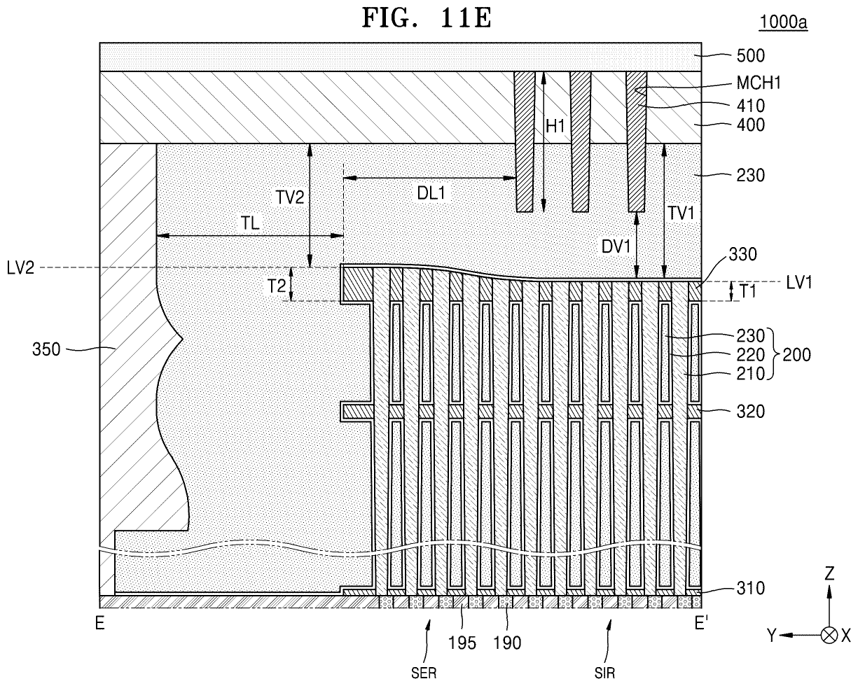

FIGS. 3A through 3D, 4A through 4D, 5A through 5D, 6A through 6D, 7A through 7D, 8A through 8D, 9A through 9D, and 10A through 10D are cross-sectional views to describe a manufacturing method of a semiconductor memory device, according to embodiments, and FIGS. 11A through 11E are cross-sectional views of the semiconductor memory device 1000a according to embodiments. FIGS. 4A, 5A, 6A, 7A, 8A, 9A, and 11A are cross-sectional views taken along line A-A′ in FIG. 1B; FIGS. 4B, 5B, 6B, 7B, 8B, 9B, and 11B are cross-sectional views taken along line B-B′ in FIG. 1B; FIGS. 4C, 5C, 6C, 7C, 8C, 9C, and 11C are cross-sectional views taken along line C-C′ in FIG. 1B; FIGS. 4D, 5D, 6D, 7D, 8D, 9D, and 11D are cross-sectional views taken along line D-D′ in FIG. 1B; and FIGS. 10A through 10D and 11E are cross-sectional views taken along line E-E′ in FIGS. 1B and 2A through 2H; and in particular, FIG. 11E is a cross-sectional view taken along line E-E′ in FIG. 2A.

Referring to FIGS. 3A through 3D together, a device separation trench 116T may be formed in a substrate 110, and a device separation layer 116 filling the device separation trench 116T may be formed. In some embodiments, the device separation trench 116T and a plurality of active regions 118 limited by the device separation trench 116T may be formed by using an extreme ultra-violet (EUV) lithography process.

The substrate 110 may include, for example, silicon (Si), crystalline Si, polycrystalline Si, or amorphous Si. In some other embodiments, the substrate 110 may include a semiconductor element such as germanium (Ge), or at least one compound semiconductor of silicon germanium (SiGe), silicon carbide (SiC), gallium arsenide (GaAs), indium arsenide (InAs), and indium phosphide (InP). In some embodiments, the substrate 110 may have a silicon on insulator (SOI) structure. For example, the substrate 110 may include a buried oxide (BOX) layer. The substrate 110 may include a conductive region, for example, a well doped with impurities, or a structure doped with impurities. The device separation layer 116 may include a material including at least one of, for example, silicon oxide, silicon nitride, and silicon oxynitride. The device separation layer 116 may have a single layer including one kind of an insulating layer, a double layer including two kinds of insulating layers, or a multiple layer including a combination of at least three kinds of insulating layers. For example, the device separation layer 116 may have a double layer or a multiple layer of an oxide layer and a nitride layer. However, according to the technical idea of the inventive concept, a configuration of the device separation layer 116 is not limited thereto.

A plurality of active regions 118 may be limited by the device separation layer 116 in the memory cell region CR on the substrate 110. In a plan view, the active region 118 may have a relatively long island shape which has both a minor axis and a major axis, like the active region ACT illustrated in FIG. 1B, and extend in the major axis. The plurality of active regions 118 may be arranged in a row in a diagonal direction with respect to the first horizontal direction (X direction) and the second horizontal direction (Y direction), and may also be arranged in a row in the second horizontal direction (Y direction).

Referring to FIGS. 4A through 4D together, by removing a portion of the active region 118 and a portion of the device separation layer 116, a plurality of word line trenches 120T may be formed in the substrate 110. The plurality of word line trenches 120T may extend in parallel with each other in the first horizontal direction (X direction), and may have a line shape in which each of the plurality of word line trenches 120T is arranged to cross the active region 118 and may generally have an equal interval in the second horizontal direction (Y direction). In some embodiments, steps may be formed on lower surfaces of the plurality of word line trenches 120T.

The gate dielectric layer 122, a plurality of word lines 120, and a plurality of buried insulating layers 124 may be sequentially formed inside the plurality of word line trenches 120T. The plurality of word lines 120 may respectively constitute the plurality of word lines WL illustrated in FIG. 1B. The plurality of word lines 120 may extend in parallel with each other in the first horizontal direction (X direction), and may have a line shape in which each of the plurality of word lines 120 is arranged to cross the active region 118 and may generally have an equal interval in the second horizontal direction (Y direction). An upper surface of each of the plurality of word lines 120 may be at a lower level than an upper surface of the substrate 110. A lower surface of the plurality of word lines 120 may have a concave-convex shape, and the plurality of active regions 118 may include transistors having a saddle fin structure (or saddle FinFETs).

Each of the plurality of word lines 120 may have a stacked structure of a lower word line layer 120a and an upper word line layer 120b. For example, the lower word line layer 120a may include a metal material, conductive metal nitride, or a combination thereof. In some embodiments, the lower word line layer 120a may include Ti, TiN, Ta, TaN, W, WN, TiSiN, WSiN, or a combination thereof. For example, the upper word line layer 120b may include doped polysilicon. In some embodiments, the lower word line layer 120a may include a core layer, and a barrier layer between the core layer and a gate dielectric layer 122.

In some embodiments, before or after the plurality of word lines 120 are formed, impurity ions may be implanted into portions of the active region 118 of the substrate 110 on both sides of the plurality of word lines 120, and a source region and a drain region may be formed inside the plurality of active regions 118.

The gate dielectric layer 122 may include at least one of silicon oxide, silicon nitride, silicon oxynitride, oxide-nitride-oxide (ONO), and high-k dielectrics having a higher dielectric constant than silicon oxide. For example, the gate dielectric layer 122 may have a dielectric constant of about 10 to about 25.

Upper surfaces of the plurality of buried insulating layers 124 may be at substantially the same level as the upper surfaces of the substrate 110. The buried insulating layer 124 may include at least one material of silicon oxide, silicon nitride, and silicon oxynitride, or a combination thereof.

In the process of forming the plurality of gate dielectric layers 122, the plurality of word lines 120, and the plurality of buried insulating layers 124, portions of upper sides of the device separation layer 116 may be removed. The plurality of active regions 118 may be limited by the device separation layer 116 on the substrate 110.

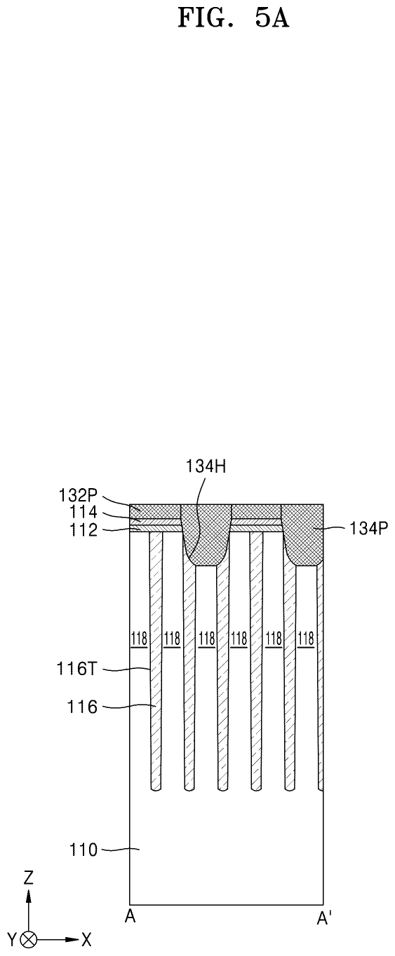

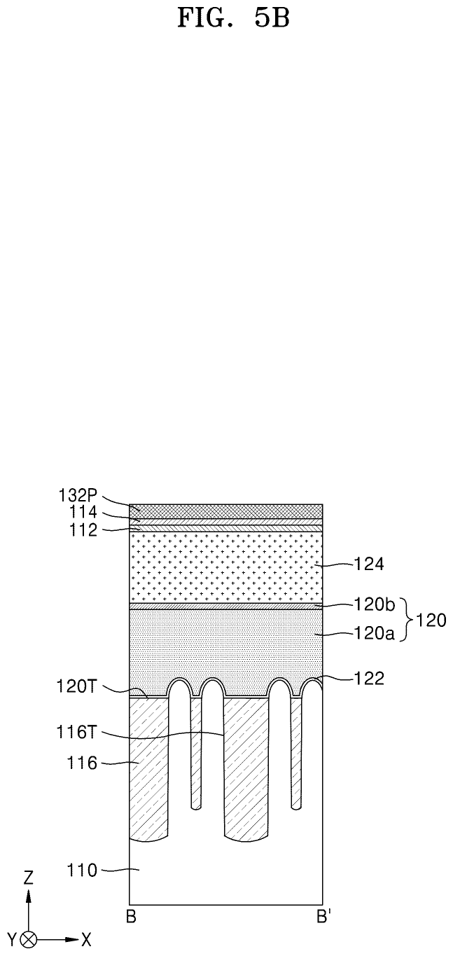

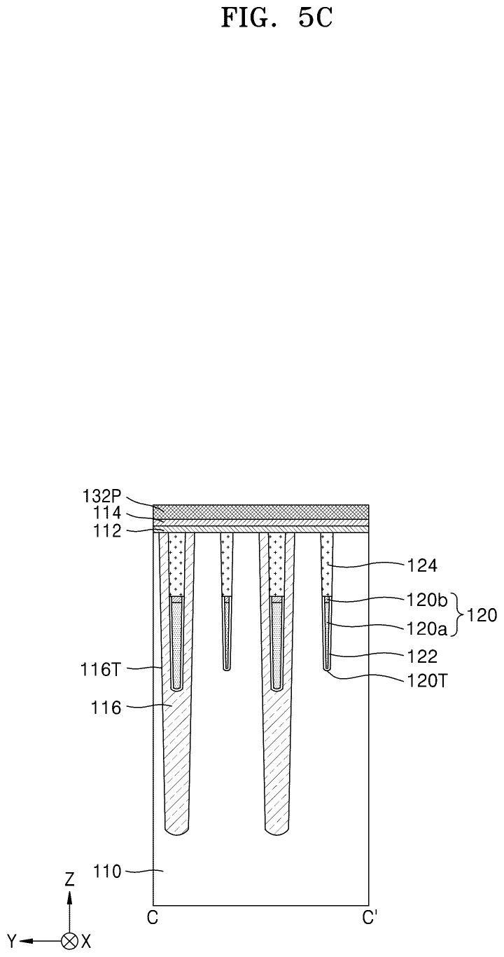

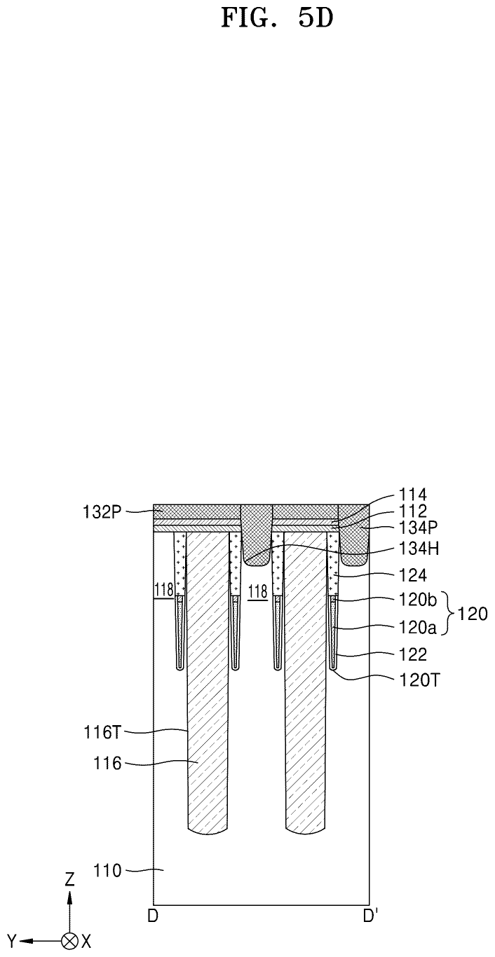

Referring to FIGS. 5A through 5D together, a first insulating layer pattern 112 and a second insulating layer pattern 114 respectively covering the device separation layer 116 and the plurality of active regions 118 may be formed. For example, the first and second insulating layer patterns 112 and 114 may include a silicon oxide layer, a silicon nitride layer, a silicon oxynitride layer, or a combination thereof. In some embodiments, the first insulating layer pattern 112 may include a silicon oxide layer, and the second insulating layer pattern 114 may include a silicon nitride layer. In some other embodiments, the first insulating layer pattern 112 may include a non-metal dielectric layer, and the second insulating layer pattern 114 may include a metal dielectric layer.

Thereafter, after a conductive semiconductor layer 132P is formed on the first and second insulating layer patterns 112 and 114, a direct contact hole 134H penetrating the conductive semiconductor layer 132P and the first and second insulating layer patterns 112 and 114, and exposing the source region in the active region 118 may be formed, and a direct contact conductive layer 134P filling the direct contact hole 134H may be formed. In some embodiments, the direct contact hole 134H may extend into the active region 118, that is, into the source region. The conductive semiconductor layer 132P may include, for example, doped polysilicon. The direct contact conductive layer 134P may include, for example, doped polysilicon. In some embodiments, the direct contact conductive layer 134P may include an epitaxial silicon layer. In some other embodiments, the direct contact conductive layer 134P may include a metal or a metal compound that is a conductive material. For example, the direct contact conductive layer 134P may include a metal, such as Ti and W, or a conductive metal which is a compound of non-metal, such as Si, C, B, and N. In some embodiments, the direct contact conductive layer 134P may include TiN, WC, or WSi.

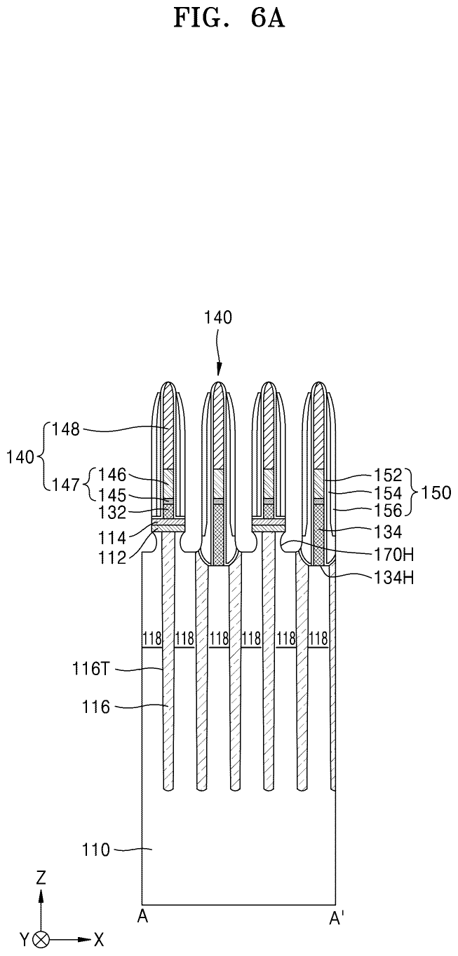

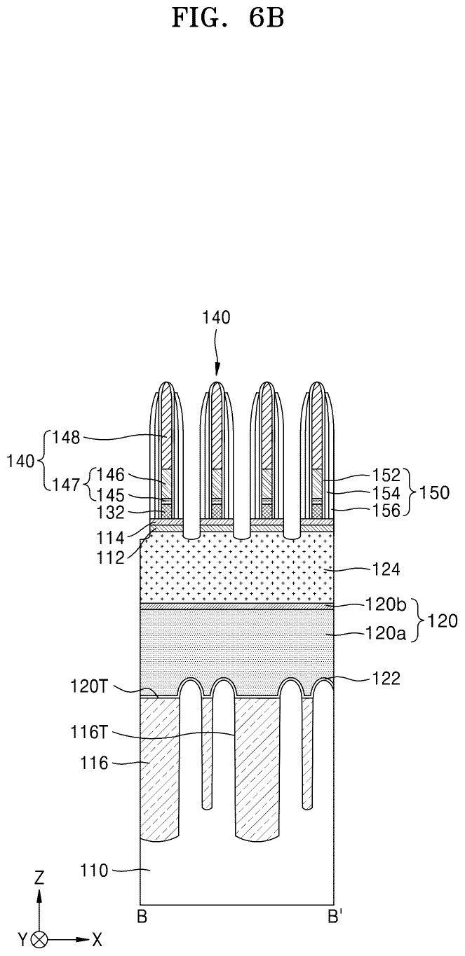

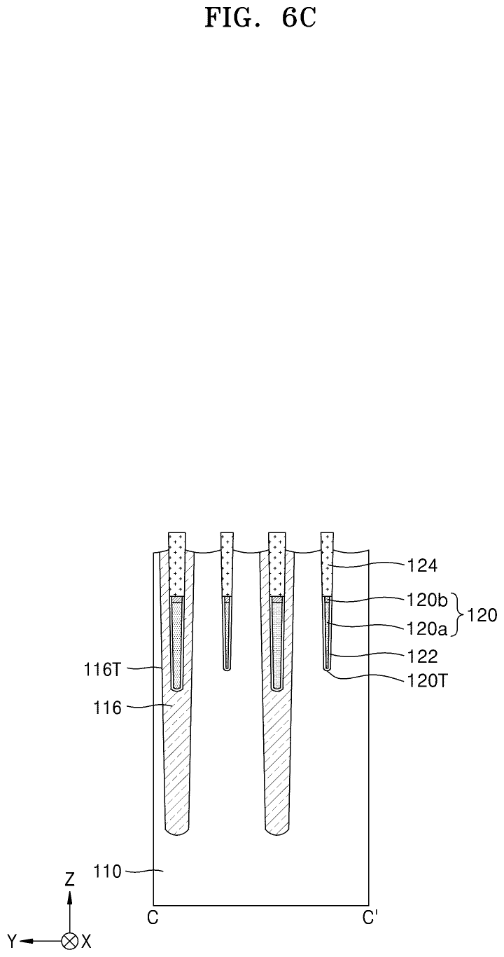

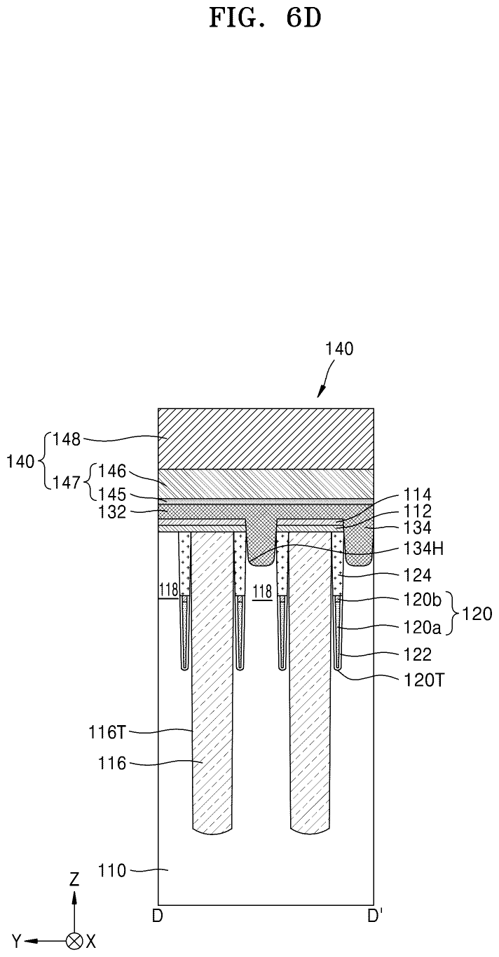

Referring to FIGS. 5A through 5D, and 6A through 6D together, a metal-based conductive layer and an insulating capping layer for covering the conductive semiconductor layer 132P and the direct contact conductive layer 134P and forming a bit line structure 140 may be sequentially formed. In some embodiments, the metal-based conductive layer may have a stacked structure including a first metal-based conductive layer and a second metal-based conductive layer. By etching the first metal-based conductive layer, the second metal-based conductive layer, and the insulating capping layer, a plurality of bit lines 147 including a first metal-based pattern 145 and a second metal-based pattern 146, which have a line shape, and a plurality of insulating capping lines 148 may be formed.

In some embodiments, the first metal-based pattern 145 may include titanium nitride (TiN) or Ti—Si—N (TSN), and the second metal-based pattern 146 may include W or tungsten silicide (WSiₓ). In some embodiments, the first metal-based pattern 145 may function as a diffusion barrier. In some embodiments, the plurality of insulating capping lines 148 may include a silicon nitride layer.

One bit line 147 and one insulating capping line 148 covering the one bit line 147 may constitute one bit line structure 140. A plurality of bit line structures 140 each including the bit line 147 and the insulating capping line 148 covering the bit line 147 may extend in parallel with each other in the second horizontal direction (Y direction) in parallel with a main surface of the substrate 110. The plurality of bit lines 147 may constitute the plurality of bit lines BL illustrated in FIG. 1B. In some embodiments, the bit line structure 140 may further include a conductive semiconductor pattern 132 which is a portion of the conductive semiconductor layer 132P arranged between the first and second insulating layer patterns 112 and 114, and the first metal-based pattern 145.

In an etching process for forming the plurality of bit lines 147, by removing by using an etching process on a portion of the conductive semiconductor layer 132P which does not vertically overlap the bit line 147 and a portion of the direct contact conductive layer 134P together, a plurality of conductive semiconductor patterns 132 and a plurality of direct contact conductive patterns 134 may be formed. In this case, the first and second insulating layer patterns 112 and 114 may function as etching stop layers in the etching process of forming the plurality of bit lines 147, the plurality of conductive semiconductor patterns 132, and the plurality of direct contact conductive patterns 134. The plurality of direct contact conductive patterns 134 may constitute a plurality of direct contacts DC illustrated in FIG. 1B. The plurality of bit lines 147 may be electrically connected to the plurality of active regions 118 via the plurality of direct contact conductive patterns 134, respectively. The conductive semiconductor pattern 132 may include, for example, doped polysilicon. The direct contact conductive pattern 134 may include doped polysilicon, a metal, or a metal compound including a conductive material. For example, the direct contact conductive pattern 134 may include a metal, such as Ti and W, or a conductive metal which is a compound of non-metal, such as Si, C, B, and N. In some embodiments, the direct contact conductive pattern 134 may include TiN, WC, or WSi.

Both sidewalls of each of the plurality of bit line structures 140 may be covered by an insulating spacer structure 150. Each of the plurality of insulating spacer structures 150 may include a first insulating spacer 152, a second insulating spacer 154, and a third insulating spacer 156. The second insulating spacer 154 may include a material having a lower dielectric constant than the first insulating spacer 152 and the third insulating spacer 156. In some embodiment, the first insulating spacer 152 and the third insulating spacer 156 may include a nitride layer, and the second insulating spacer 154 may include an oxide layer. In some embodiments, the first insulating spacer 152 and the third insulating spacer 156 may include a nitride layer, and the second insulating spacer 154 may include a material having an etching selectivity with respect to the first insulating spacer 152 and the third insulating spacer 156. For example, when the first insulating spacer 152 and the third insulating spacer 156 include a nitride layer, the second insulating spacer 154 may include an oxide layer, but may be removed in a subsequent process to become an air spacer.

A plurality of buried contact holes 170H may be formed between each of the plurality of bit lines 147. The plurality of buried contact holes 170H may have an inside space limited by the insulating spacer structure 150, which covers sidewalls of each of two neighboring bit lines 147 between the two neighboring bit lines 147 among the plurality of bit lines 147, and by the active region 118.

The plurality of buried contact holes 170H may be formed by removing portions of the first and second insulating layer patterns 112 and 114 and the active region 118 by using the plurality of insulating capping lines 148 and the insulating spacer structure 150 covering both sidewalls of each of the plurality of bit line structures 140 as etching masks. In some embodiments, after performing firstly an anisotropic etching process of removing portions of the first and second insulating layer patterns 112 and 114 and the active region 118 by using the plurality of insulating capping lines 148 and the insulating spacer structure 150 covering both sidewalls of each of the plurality of bit line structures 140 as etching masks, and by performing an isotropic etching process of further removing other portions of the active region 118, the plurality of buried contact holes 170H may be formed to have an expanded space that is limited by the active region 118.

The plurality of gate line patterns GLP may be formed in the periphery region PR illustrated in FIG. 1B. The plurality of gate line patterns GLP may be formed together with the plurality of bit lines 147. In other words, the gate line pattern GLP may have a stacked structure of the first metal-based pattern 145 and the second metal-based pattern 146.

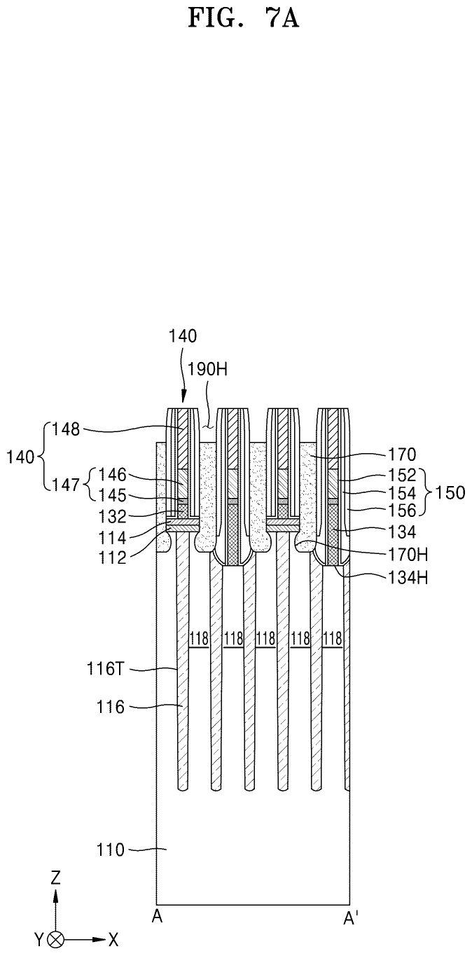

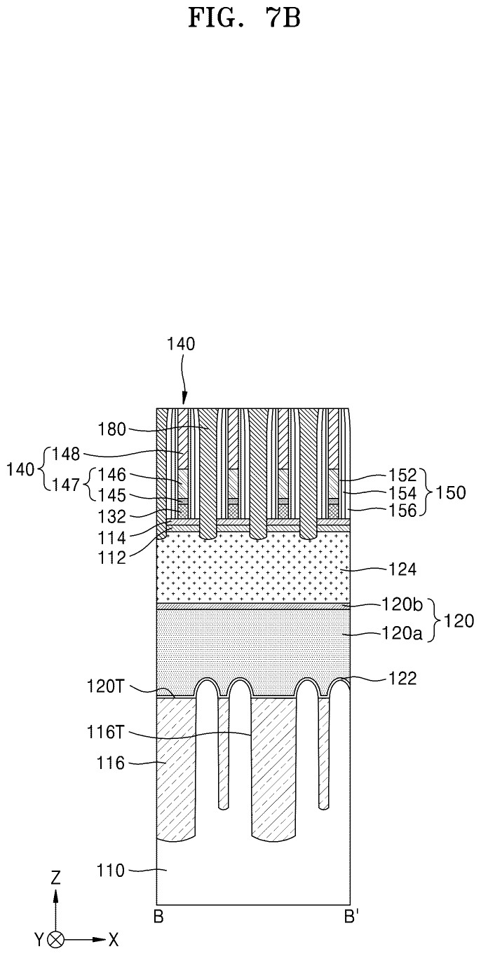

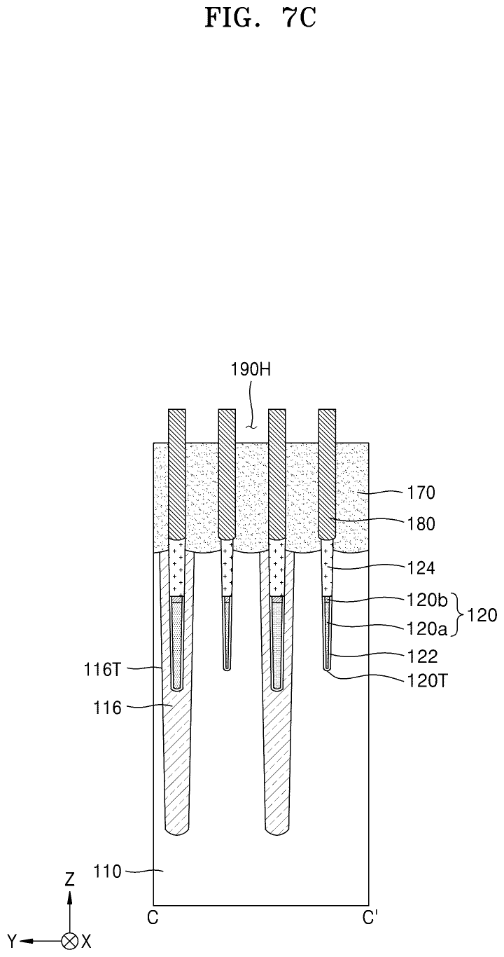

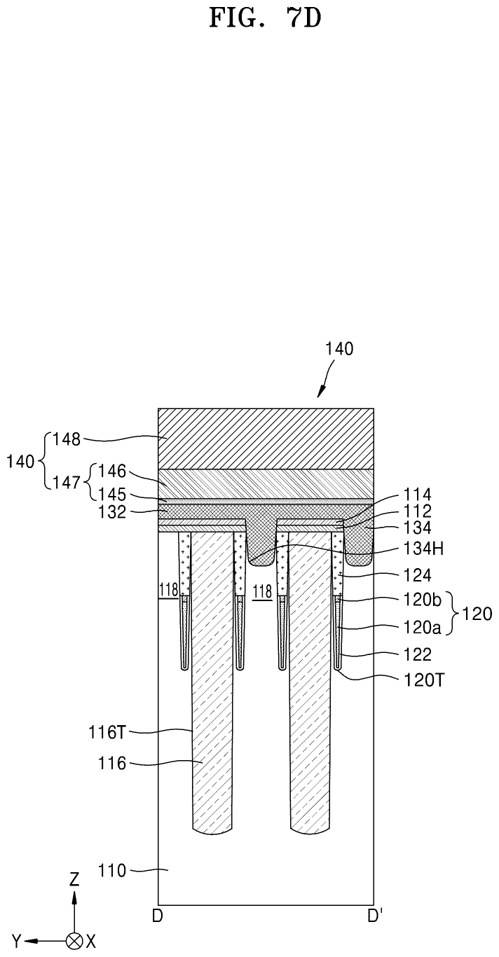

Referring to FIGS. 7A through 7D together, a plurality of buried contacts 170 and a plurality of insulating fences 180 may be formed in spaces between each of the plurality of insulating spacer structures 150 which respectively cover both sidewalls of the plurality of bit line structures 140. The plurality of buried contacts 170 and the plurality of insulating fences 180 may be alternately arranged, along a space between a pair of insulating spacer structures 150 facing each other among the plurality of insulating spacer structures 150 which respectively cover both sidewalls of the plurality of bit line structures 140, that is, in the second horizontal direction (Y direction). For example, the plurality of buried contacts 170 may include polysilicon. For example, the plurality of insulating fences 180 may include a nitride layer.

In some embodiments, the plurality of buried contacts 170 may be arranged in a line in each of the first horizontal direction (X direction) and the second horizontal direction (Y direction). Each of the plurality of buried contacts 170 may extend from the active region 118 in the vertical direction (Z direction) orthogonal to the substrate 110. The plurality of buried contacts 170 may constitute the plurality of buried contacts BC illustrated in FIG. 1B.

The plurality of buried contacts 170 may be arranged in spaces limited by the plurality of insulating fences 180 and the plurality of insulating spacer structures 150 which respectively cover both sidewalls of the plurality of bit line structures 140. The plurality of buried contacts 170 may fill lower portions of the spaces between each of the plurality of insulating spacer structures 150 which respectively cover both sidewalls of the plurality of bit line structures 140.

Levels of upper surfaces of the plurality of buried contacts 170 may be lower than levels of upper surfaces of the plurality of insulating capping lines 148. Upper surfaces of the plurality of insulating fences 180 and the upper surfaces of the plurality of insulating capping lines 148 may be at the same level with respect to the vertical direction (Z direction).

A plurality of landing pad holes 190H may be respectively limited by the plurality of insulating spacer structures 150 and the plurality of insulating fences 180. The plurality of buried contacts 170 may be respectively exposed to lower surfaces of the plurality of landing pad holes 190H.

In a process of forming the plurality of buried contacts 170 and/or the plurality of insulating fences 180, portions of the upper sides of the insulating capping line 148 included in the bit line structure 140, and the insulating spacer structure 150 may be removed, and thus, a level of the upper surface of the bit line structure 140 may be lowered.

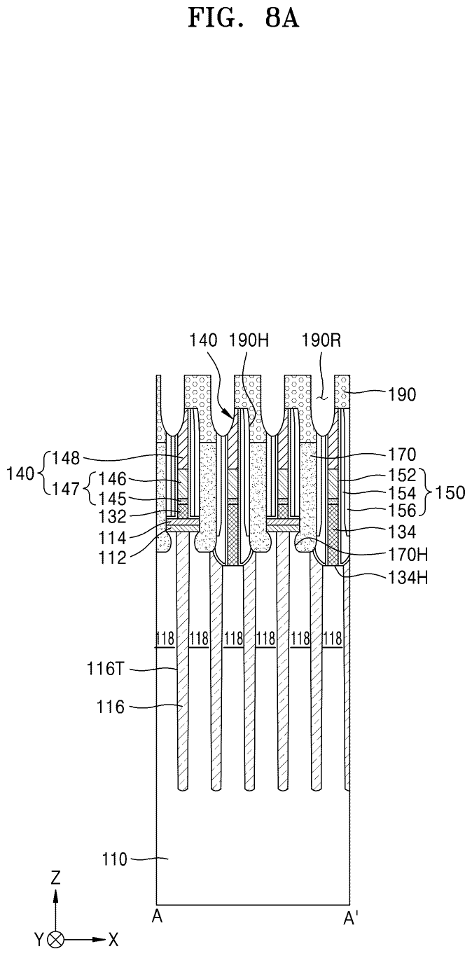

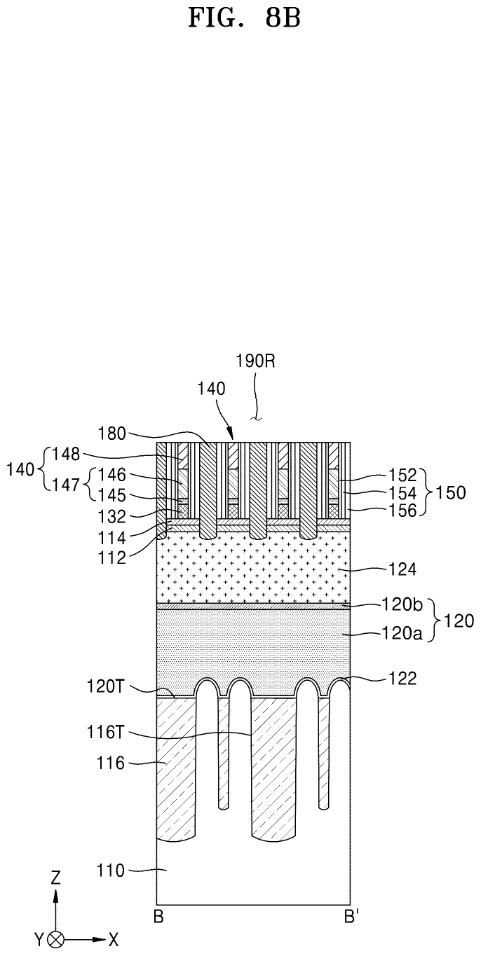

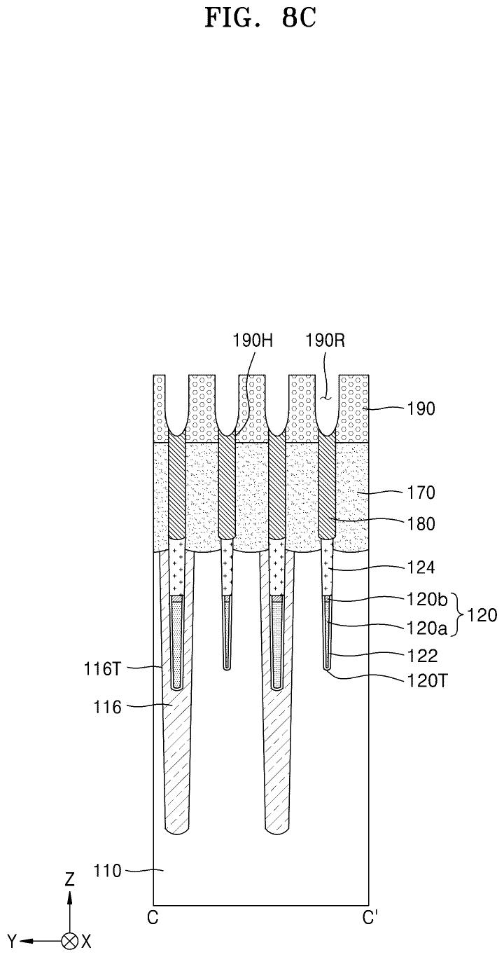

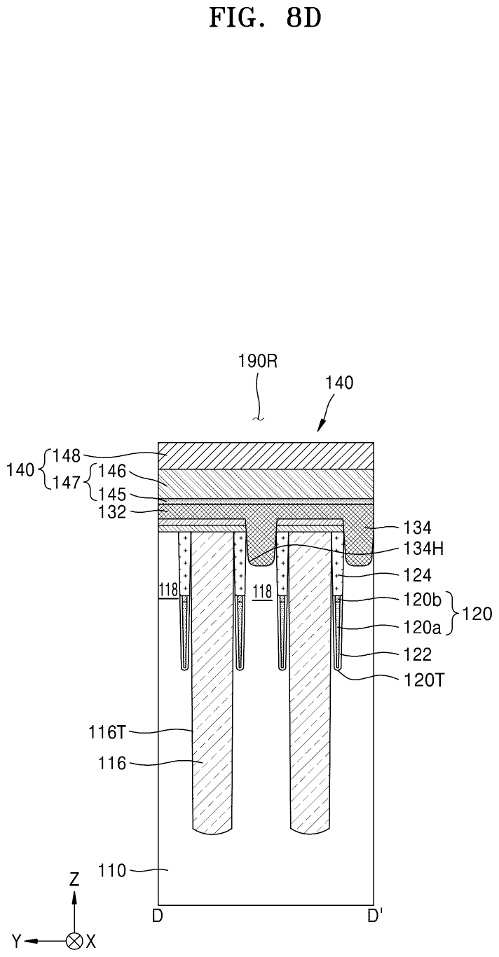

Referring to FIGS. 8A through 8D together, a landing pad material layer filling the plurality of landing pad holes 190H and covering the plurality of bit line structures 140 may be formed. In some embodiments, the landing pad material layer may include a conductive barrier layer and a conductive pad material layer on the conductive barrier layer. For example, the conductive barrier layer may include a metal, a conductive metal nitride, or a combination thereof. In some embodiments, the conductive barrier layer may have a Ti/TiN stacked structure. In some embodiments, the conductive pad material layer may include W.

In some embodiments, before the landing pad material layer is formed, a metal silicide layer may be formed on the plurality of buried contacts 170. The metal silicide layer may be arranged between the plurality of buried contacts 170 and the landing pad material layer. The metal silicide layer may include cobalt silicide (CoSiₓ), nickel silicide (NiSiₓ), or manganese silicide (MnSiₓ), but is not limited thereto.

Thereafter, by removing a portion of the landing pad material layer, a plurality of landing pads 190 filling at least a portion of the plurality of landing pad holes 190H, extending onto the plurality of bit line structures 140, and being separated into plurality by a recess portion 190R may be formed.

The plurality of landing pads 190 may be apart from each other with the recess portion 190R therebetween. The plurality of landing pads 190 may be respectively arranged on the plurality of buried contacts 170, and may respectively extend onto the plurality of bit line structures 140. In some embodiments, the plurality of landing pads 190 may respectively extend onto the plurality of bit lines 147. The plurality of landing pads 190 may be arranged on the plurality of buried contacts 170, and the plurality of buried contacts 170 and the plurality of landing pads 190 corresponding to each other may be electrically connected to each other. The buried contact 170 and the landing pad 190 corresponding to each other may be referred to as contact plugs together. The plurality of landing pads 190 may be connected to the active region 118 via the plurality of buried contacts 170, respectively. The plurality of landing pads 190 may constitute the plurality of landing pads LP illustrated in FIG. 1B.

The buried contact 170 may be arranged between two adjacent bit line structures 140, and the landing pad 190 may extend, from a space between two adjacent bit line structures 140 with the buried contact 170 therebetween, onto one bit line structure 140.

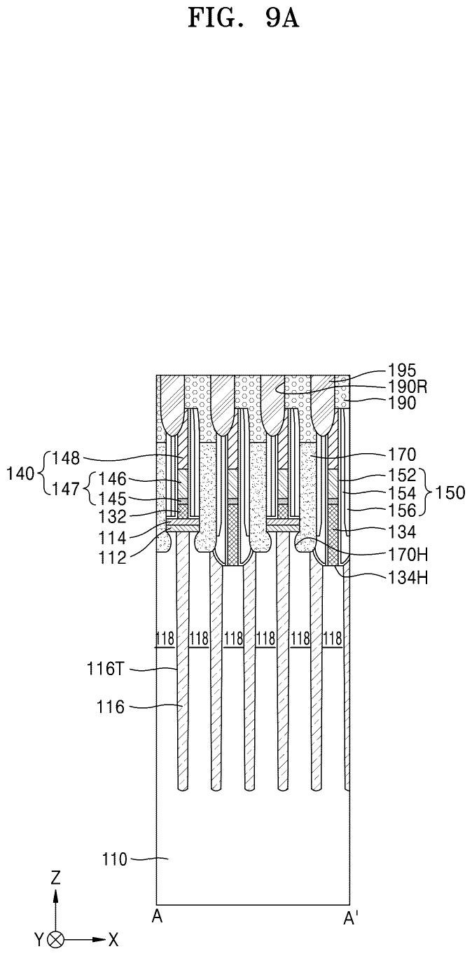

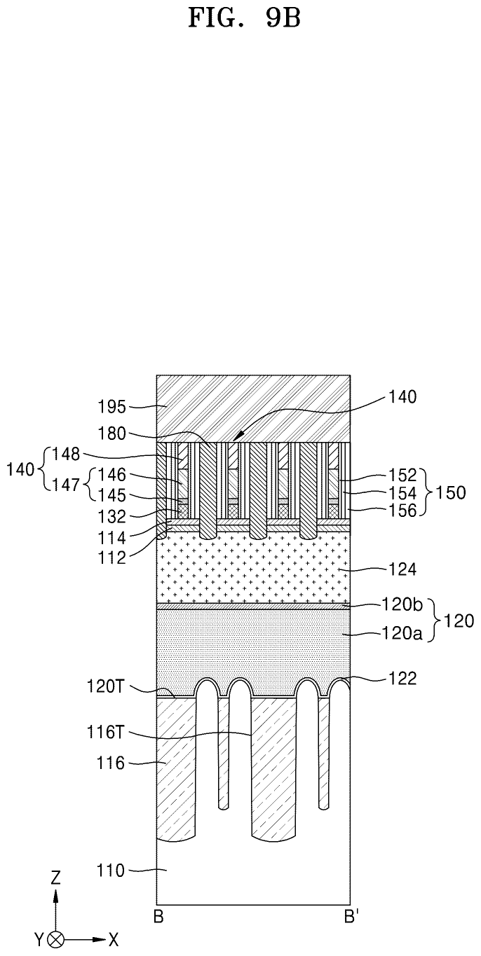

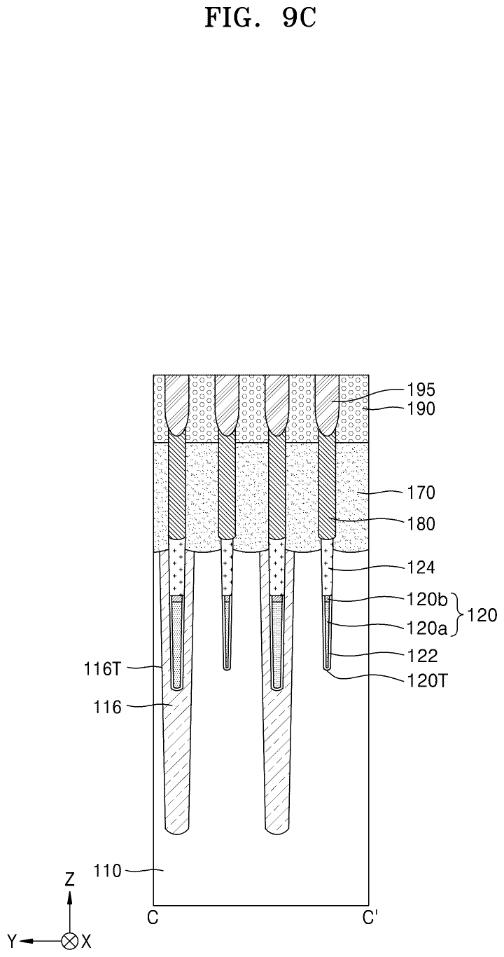

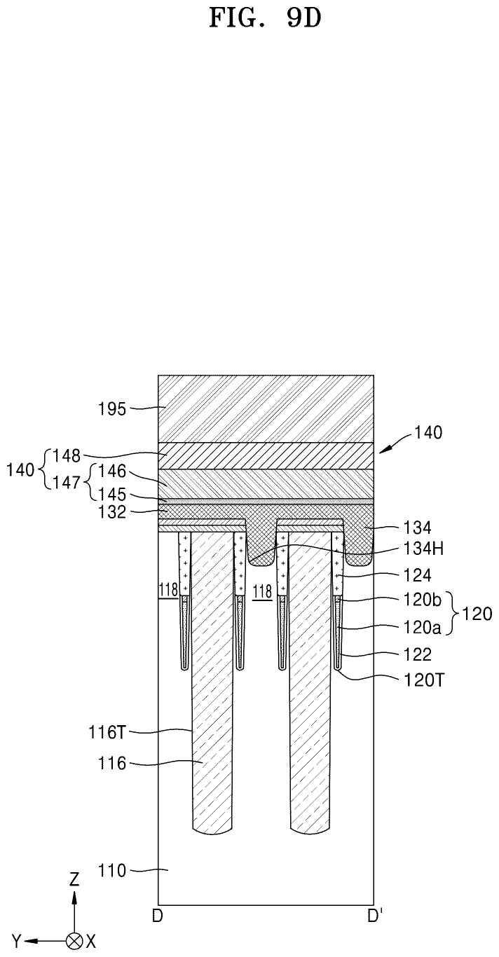

Referring to FIGS. 9A through 9D, an insulating structure 195 filling the recess portion 190R may be formed. In some embodiments, the insulating structure 195 may include an interlayer insulating layer and an etching stop layer. For example, the interlayer insulating layer may include oxide, and the etching stop layer may include nitride. FIGS. 9A and 9C illustrate that an upper surface of the insulating structure 195 and an upper surface of the landing pad 190 are at the same level, but the embodiment is not limited thereto.

Referring to FIG. 10A, the plurality of lower electrodes 210 respectively connected to the plurality of landing pads 190, and a plurality of support patterns (that is, 310, 320, and 330), which are in contact with sidewalls of the plurality of lower electrodes 210 and support the plurality of lower electrodes 210, may be formed. The plurality of support patterns (that is, 310, 320, and 330) may include a lower support pattern 310, an intermediate support pattern 320, and an upper support pattern 330, which are in contact with the sidewalls of the plurality of lower electrodes 210 and are at different vertical levels to be apart from each other in the vertical direction (Z direction). The upper, intermediate, and lower support patterns 310, 320, and 330 may be referred to as a first support pattern 310, a second support pattern 320, and a third support pattern 330, respectively. After a mold layer between each of the upper, intermediate, and lower support patterns 310, 320, and 330 is formed, and a plurality of through holes, which penetrate the upper, intermediate, and lower support patterns 310, 320, and 330, and then the mold layer, and expose the plurality of landing pads 190 on lower surfaces thereof, are formed, the plurality of lower electrodes 210 may be formed by filling the plurality of through holes with a conductive material and by removing the mold layer. In some embodiments, a plurality of openings used as paths for removing the mold layer may be arranged in each of the upper, intermediate, and lower support patterns 310, 320, and 330.

The lower support pattern 310 may be at a high vertical level from the plurality of landing pads 190 in the vertical direction (Z direction) to be in contact with the sidewalls of the plurality of lower electrodes 210, the intermediate support pattern 320 may be a high vertical level from the lower support pattern 310 in the vertical direction (Z direction) to be in contact with the sidewalls of the plurality of lower electrodes 210, and the upper support pattern 330 may be at a high vertical level from the intermediate support pattern 320 in the vertical direction (Z direction) to be in contact with the sidewalls of the plurality of lower electrodes 210. The lower support pattern 310 may be in contact with the sidewalls of the plurality of lower electrodes 210 near lower end portions of the plurality of lower electrodes 210 in the vertical direction (Z direction). FIG. 10A illustrates that a lower surface of the lower support pattern 310 and a lower surface of the plurality of lower electrodes 210 are at the same vertical level, but the embodiment is an example and is not limited thereto. In some embodiments, the lower surface of the lower support pattern 310 may be at a vertical level higher than the lower surface of the plurality of lower electrodes 210, and may be apart from the plurality of landing pads 190 and the insulating structure 195 in the vertical direction (Z direction). In some embodiments, the intermediate support pattern 320 may be in contact with the sidewalls of the plurality of lower electrodes 210 at a vertical level higher than the center of the plurality of lower electrodes 210 in the vertical direction (Z direction). For example, the intermediate support pattern 320 may be at a vertical level lower than the uppermost end of the plurality of lower electrodes 210 and higher than the center of the plurality of lower electrodes 210 in the vertical direction (Z direction), and may be in contact with the sidewalls of the plurality of lower electrodes 210. The upper support pattern 330 may be in contact with upper end sidewalls of the plurality of lower electrodes 210. In some embodiments, an upper surface of a portion of the upper support pattern 330 in contact with the sidewall of any one lower electrode 210 among the plurality of lower electrodes 210 and an upper surface of any one lower electrode 210 may be at the same vertical level. Each of the lower support pattern 310, the intermediate support pattern 320, and the upper support pattern 330 may include any one of silicon nitride (SiN), silicon carbon nitride (SiCN), N-rich SiN, and Si-rich SiN, but is not limited thereto.

In a plan view, an upper surface of the upper support pattern 330 may be at a first vertical level LV1 inside the upper support pattern 330, and may be at a second vertical level LV2 higher than the first vertical level LV1 at the edge of the upper support pattern 330. For example, the second vertical level LV2 may be at a vertical level higher than the first vertical level LV1 by about 10 nm to about 30 nm. In a plan view, the upper support pattern 330 may have a first thickness T1 therein, and may have a second thickness T2 greater than the first thickness T1 at an edge thereof. For example, the second thickness T2 may be greater than the first thickness T1 by about 10 nm to about 30 nm.

The plurality of lower electrodes 210 may be respectively and electrically connected to the plurality of landing pads 190. Each of the plurality of lower electrodes 210 may have a column shape with a filled inner portion thereof, that is, a pillar shape having a circular horizontal cross-section, but is not limited thereto. In some embodiments, each of the plurality of lower electrodes 210 may have a cylinder shape having a closed lower portion thereof. In some embodiments, the plurality of lower electrodes 210 may be arranged in a honeycomb zigzag shape with respect to the first horizontal direction (X direction) or the second horizontal direction (Y direction). In some other embodiments, the plurality of lower electrodes 210 may be arranged in a line matrix shape in each of the first horizontal direction (X direction) and the second horizontal direction (Y direction). In some embodiments, each of the plurality of lower electrodes 210 may have a tapered shape, in which each of the plurality of lower electrodes 210 extends from a lower side to an upper side with an increasing horizontal width thereof in the vertical direction (Z direction). The plurality of lower electrodes 210 may include, for example, silicon doped with impurities, a metal, such as W and copper, or a conductive metal compound such as titanium nitride.

Referring to FIG. 10B, a capacitor dielectric layer 220 and the upper electrode 230 may be sequentially formed on the plurality of lower electrodes 210. The plurality of lower electrodes 210, the capacitor dielectric layer 220, and the upper electrode 230 may constitute a plurality of capacitor structures 200. The capacitor dielectric layer 220 may conformally cover surfaces of the plurality of lower electrodes 210. In some embodiments, the capacitor dielectric layer 220 and the upper electrode 230 may be formed in one body to cover the plurality of lower electrodes 210 together in a certain region, for example, in one memory cell region (CR in FIG. 1B).

The capacitor dielectric layer 220 may include, for example, TaO, TaAlO, TaON, AlO, AlSiO, HfO, HfSiO, ZrO, ZrSiO, TiO, TiAlO, (Ba,Sr)TiO (BST), SrTiO (STO), BaTiO (BTO), (Pb, Zr, Ti) (PZT)O, (Pb,La)(Zr,Ti)O, Ba(Zr,Ti)O, Sr(Zr,Ti)O, or a combination thereof.

The upper electrode 230 may include, for example, W, Ru, RuO, Pt, PtO, Ir, IrO, SrRuO (SRO), (Ba,Sr)RuO (BSRO), CaRuO (CRO), BaRuO, La(Sr,Co)O, etc. In some embodiments, the upper electrode 230 may include a metal material. For example, the upper electrode 230 may include W.

The upper electrode 230 may have the side surface thickness TL on the side surface of the upper support pattern 330 in a horizontal direction. In a plan view, the edge of the upper electrode 230 and the edge of the upper support pattern 330 may be apart from each other by the side surface thickness TL. The side surface thickness TL may be less than about 300 nm. For example, the side surface thickness TL may be about 230 nm to about 270 nm.

Referring to FIG. 10C, a buried insulating layer 350 covering the plurality of capacitor structures 200 may be formed. For example, the buried insulating layer 350 may include an oxide layer or an ultra low K (ULK) layer. The oxide layer may be formed of any one layer of a boro phosphor silicate glass (BPSG) layer, a phosphor silicate glass (PSG) layer, a boro silicate glass (BSG) layer, an un-doped silicate glass (USG) layer, a tetra ethyl ortho silicate (TEOS) layer, and a high density plasma (HDP) layer. The ULK layer may include, for example, any one layer of an SiOC layer and an SiCOH layer, which have an ultra low dielectric constant K of about 2.2 to about 2.4. In some embodiments, an upper surface of the buried insulating layer 350 may be at a vertical level higher than an upper surface of the upper electrode 230.

Referring to FIGS. 10C and 10D together, by removing a portion of an upper side of the upper electrode 230 and a portion of an upper side of the buried insulating layer 350, the upper electrode 230 may be exposed. By removing the portion of the upper side of the upper electrode 230 and the portion of the upper side of the buried insulating layer 350, the upper surface of the upper electrode 230 may be planarized. For example, the upper surface of the upper electrode 230 and the upper surface of the buried insulating layer 350 may be substantially at the same vertical level to form a coplanar surface together.

Referring to FIGS. 11A through 11E together, the semiconductor memory device 1000a may be formed, by forming a cover insulating layer 400 covering the buried insulating layer 350 and the upper electrode 230, the plurality of first wiring contact plugs 410 penetrating the cover insulating layer 400 and extending into the upper electrode 230, and the plurality of wiring lines 500 arranged on the cover insulating layer 400 and the plurality of first wiring contact plugs 410 and respectively connected to the plurality of first wiring contact plugs 410.

For example, the cover insulating layer 400 may include silicon oxide. The cover insulating layer 400 may include, for example, an oxide layer or a ULK layer. After a plurality of first contact holes MCH1 penetrating the cover insulating layer 400 and extending into the upper electrode 230 are formed, by filling the plurality of first contact holes MCH1 with a conductive material, the plurality of first wiring contact plugs 410 may be formed. The plurality of first wiring contact plugs 410 may include a wiring contact barrier layer covering a surface exposed inside the plurality of first contact holes MCH1, and a wiring contact charging layer covering the wiring contact barrier layer and filling the plurality of first contact holes MCH1. For example, the wiring contact barrier layer may include a metal such as, Ti, Ta, TiN, and TaN, or conductive metal nitride. For example, the wiring contact charging layer may include a metal such as W. Each of the plurality of first contact holes MCH1 and the plurality of first wiring contact plugs 410 may have a tapered shape extending from a lower side to an upper side with an increasing horizontal width in the vertical direction (Z direction).

The plurality of wiring lines 500 may be formed on the cover insulating layer 400. At least some wiring lines among the plurality of wiring lines 500 may be connected to the plurality of first contact holes MCH1, and may provide power to the upper electrode 230. The plurality of wiring lines 500 may include a metal, for example, Al, Cu, W, etc.

Referring to FIGS. 2A and 11E together, in a plan view, the plurality of first wiring contact plugs 410 may be apart from the edge of the upper support pattern 330 into the upper support pattern 330 by at least the first horizontal separation distance DL1. In other words, in a plan view, the first wiring contact plug 410 closest to the edge of the upper support pattern 330 among the plurality of first wiring contact plugs 410 may be apart from the edge of the upper support pattern 330 by the first horizontal separation distance DL1. The plurality of first wiring contact plugs 410 may be arranged on portions where the upper support pattern 330 has the first thickness T1. The plurality of first wiring contact plugs 410 may be arranged on portions where the upper surface of the upper support pattern 330 is at the first vertical level LV1.

The side surface thickness TL, that is a thickness in the horizontal direction of a portion of the upper electrode 230 covering the side surfaces of the upper support pattern 330, may be less than about 300 nm. For example, the side surface thickness TL may be about 230 nm to about 270 nm. The maximum value of a thickness in the vertical direction (Z direction) of a portion of the upper electrode 230 covering the upper surface of the upper support pattern 330 may be a first vertical thickness TV1, and the minimum value thereof may be a second vertical thickness TV2 less than the first vertical thickness TV1. Each of the first vertical thickness TV1 and the second vertical thickness TV2 may be less than the side surface thickness TL. In a plan view, the first vertical thickness TV1 may be a thickness of portions of the upper electrode 230 connected to the plurality of first wiring contact plugs 410, that is, a thickness of portions in the vertical direction (Z direction) of the upper electrode 230 in the inner support region SIR, and the second vertical thickness TV2 may be a thickness of portions in the vertical direction (Z direction) of the upper electrode 230 on the edge of the upper support pattern 330. The first vertical thickness TV1 may be greater than the second vertical thickness TV2 by about 10 nm to about 30 nm. In a plan view, each of the plurality of first wiring contact plugs 410 may be apart from the edge of the upper support pattern 330 by the first horizontal separation distance DL1 greater than the side surface thickness TL. For example, the first horizontal separation distance DL1 may be about 300 nm.

Each of the plurality of first wiring contact plugs 410 may have the same first vertical height H1 in the vertical direction (Z direction). The lower surface of each of the plurality of first wiring contact plugs 410 may be apart, from the upper surface of the capacitor dielectric layer 220 covering the upper surface of the upper support pattern 330 and the upper surface of the lower electrode 210, in the vertical direction (Z direction) by the same separation distance as a first vertical separation distance DV1. In other words, the vertical thickness of the portion of the upper electrode 230 between the lower surface of each of the plurality of first wiring contact plugs 410 and the upper surface of the portion of the capacitor dielectric layer 220 may generally have the same value, that is, the first vertical separation distance DV1.

Referring to FIGS. 2A and 11A through 11E together, because the separation distance between each of the plurality of first wiring contact plugs 410 and the capacitor dielectric layer 220 is generally the same, the deviation of electrical characteristics of each of the plurality of capacitor structures 200 constituting the plurality of memory cells may be reduced, and thus, the reliability of the semiconductor memory device 1000a may be secured.

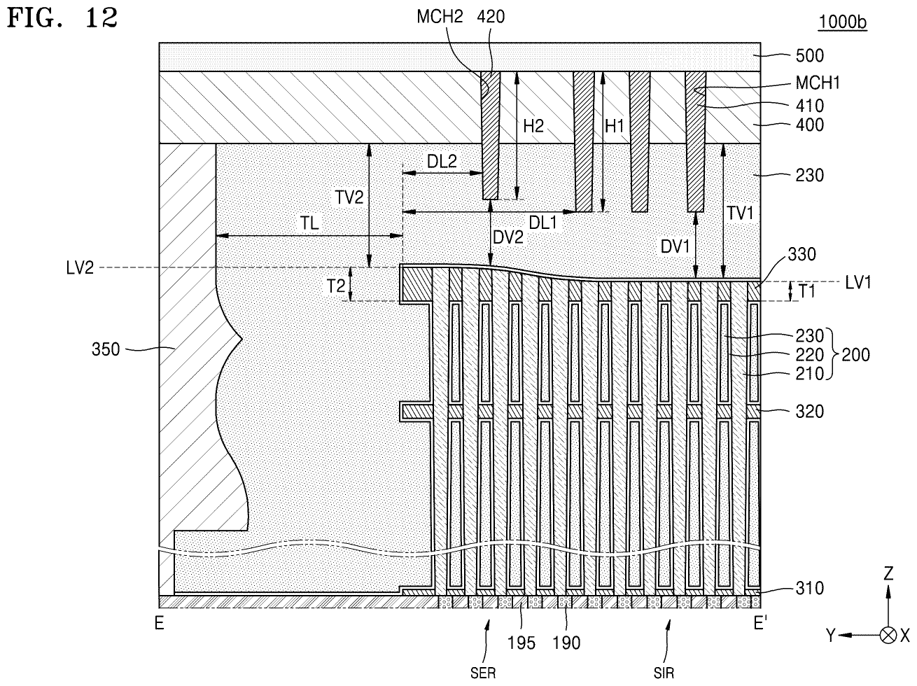

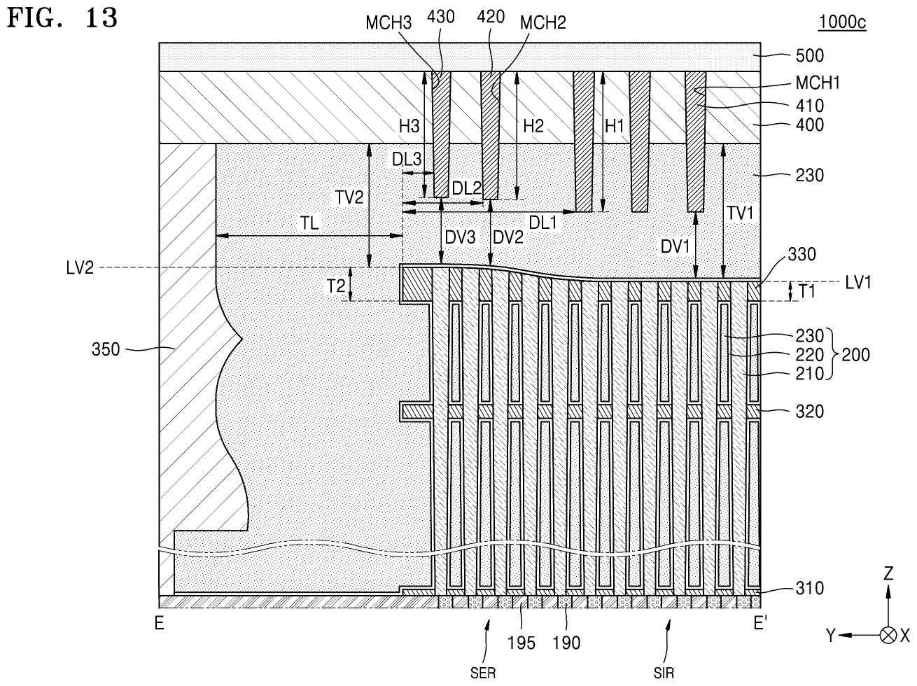

FIGS. 12 and 13 are cross-sectional views of semiconductor memory devices 1000b and 1000c, respectively according to embodiments. FIGS. 12 and 13 are cross-sectional views taken along line E-E′ in FIGS. 1B, and 2A through 2H, respectively, and in particular, FIG. 12 is a cross-sectional view taken along line E-E′ in FIG. 2B, and FIG. 13 is a cross-sectional view taken along line E-E′ in FIG. 2C.

Referring to FIGS. 2B and 12 together, the semiconductor memory device 1000b may be formed, by forming the cover insulating layer 400 covering the buried insulating layer 350 and the upper electrode 230, the plurality of first wiring contact plugs 410 and the plurality of second wiring contact plugs 420, which penetrate the cover insulating layer 400 and extend into the upper electrode 230, and the plurality of wiring lines 500 arranged on the cover insulating layer 400, the plurality of first wiring contact plugs 410, and the plurality of second wiring contact plugs 420, and connected to the plurality of first wiring contact plugs 410 and the plurality of second wiring contact plugs 420.

The plurality of first wiring contact plugs 410 may be formed by filling the plurality of first contact holes MCH1 after the plurality of first contact holes MCH1 penetrating the cover insulating layer 400 and extending into the upper electrode 230 are formed, and the plurality of second wiring contact plugs 420 may be formed by filling a plurality of second contact holes MCH2 after the plurality of second contact holes MCH2 penetrating the cover insulating layer 400 and extending into the upper electrode 230 are formed. The plurality of first contact holes MCH1 and the plurality of second contact holes MCH2 may be formed together by using the same etching process, and the plurality of first wiring contact plugs 410 and the plurality of second wiring contact plugs 420 may be formed together by simultaneously filling the plurality of first contact holes MCH1 and the plurality of second contact holes MCH2, respectively. Each of the plurality of first contact holes MCH1, the plurality of second contact holes MCH2, the plurality of first wiring contact plugs 410, and the plurality of second wiring contact plugs 420 may extend from a lower side to an upper side in the vertical direction (Z direction) and have a tapered shape with an increasing horizontal width.

In a plan view, the plurality of first wiring contact plugs 410 may be apart from the edge of the upper support pattern 330 into the upper support pattern 330 by at least the first horizontal separation distance DL1, and the plurality of second wiring contact plugs 420 may be apart from the edge of the upper support pattern 330 into the upper support pattern 330 by a second horizontal separation distance DL2 less than the first horizontal separation distance DL1. The first horizontal separation distance DL1 may be greater than the side surface thickness TL, and the second horizontal separation distance DL2 may be less than the side surface thickness TL.

At the same vertical level, a horizontal area of each of the plurality of second contact holes MCH2 and the plurality of second wiring contact plugs 420 may be less than a horizontal area of each of the plurality of first contact holes MCH1 and the plurality of first wiring contact plugs 410, respectively. When the plurality of first contact holes MCH1 and the plurality of second contact holes MCH2 are formed together, due to a difference in the horizontal areas thereof, an extension length of the plurality of second contact holes MCH2 may be formed shorter than an extension length of the plurality of first contact holes MCH1. Accordingly, each of the plurality of first wiring contact plugs 410 may have the same first vertical height H1, and each of the plurality of second wiring contact plugs 420 may have a second vertical height H2 less than the first vertical height H1 in the vertical direction (Z direction).

From the upper surface of a portion of the capacitor dielectric layer 220 covering the upper surface of the upper support pattern 330 and the upper surface of the lower electrode 210, a lower surface of each of the plurality of first wiring contact plugs 410 may be apart by the same separation distance as the first vertical separation distance DV1 in the vertical direction (Z direction), and a lower surface of each of the plurality of second wiring contact plugs 420 may be apart by a second vertical separation distance DV2 in the vertical direction (Z direction). The first vertical separation distance DV1 and the second vertical separation distance DV2 may have generally the same value.

Because the separation distances between each of the plurality of first wiring contact plugs 410 and the plurality of second wiring contact plugs 420 and the capacitor dielectric layer 220 are generally the same, the deviation of electrical characteristics of each of the plurality of capacitor structures 200 constituting the plurality of memory cells may be reduced, and thus, the reliability of the semiconductor memory device 1000b according to the inventive concept may be secured.

Referring to FIGS. 2C and 13 together, the semiconductor memory device 1000c may be formed, by forming the cover insulating layer 400 covering the buried insulating layer 350 and the upper electrode 230, the plurality of first wiring contact plugs 410, the plurality of second wiring contact plugs 420, and the plurality of third wiring contact plugs 430, which penetrate the cover insulating layer 400 and extend into the upper electrode 230, and the plurality of wiring lines 500 arranged on the cover insulating layer 400, the plurality of first wiring contact plugs 410, the plurality of second wiring contact plugs 420, and the plurality of third wiring contact plugs 430 and connected to the plurality of first wiring contact plugs 410, the plurality of second wiring contact plugs 420, and the plurality of third wiring contact plugs 430.

The plurality of first wiring contact plugs 410 may be formed by filling the plurality of first contact holes MCH1 with a conductive material after the plurality of first contact holes MCH1 penetrating the cover insulating layer 400 and extending into the upper electrode 230 are formed, the plurality of second wiring contact plugs 420 may be formed by filling the plurality of second contact holes MCH2 with a conductive material after the plurality of second contact holes MCH2 penetrating the cover insulating layer 400 and extending into the upper electrode 230 are formed, and the plurality of third wiring contact plugs 430 may be formed by filling a plurality of third contact holes MCH3 with a conductive material after the plurality of third contact holes MCH3 penetrating the cover insulating layer 400 and extending into the upper electrode 230 are formed. The plurality of first contact holes MCH1, the plurality of second contact holes MCH2, and the plurality of third contact holes MCH3 may be formed together by using the same etching process, and the plurality of first wiring contact plugs 410, the plurality of second wiring contact plugs 420, and the plurality of third wiring contact plugs 430 may be formed together by simultaneously filling the plurality of first contact holes MCH1, the plurality of second contact holes MCH2, and the plurality of third contact holes MCH3 with a conductive material, respectively. Each of the plurality of first contact holes MCH1, the plurality of second contact holes MCH2, the plurality of third contact holes MCH3, the plurality of first wiring contact plugs 410, the plurality of second wiring contact plugs 420, and the plurality of third wiring contact plugs 430 may extend from a lower side to an upper side thereof in the vertical direction (Z direction), and have a tapered shape with an increasing horizontal width thereof.

In a plan view, the plurality of first wiring contact plugs 410 may be apart from the edge of the upper support pattern 330 into the upper support pattern 330 by the first horizontal separation distance DL1, the plurality of second wiring contact plugs 420 may be apart from the edge of the upper support pattern 330 into the upper support pattern 330 by the second horizontal separation distance DL2 less than the first horizontal separation distance DL1, and the plurality of third wiring contact plugs 430 may be apart from the edge of the upper support pattern 330 into the upper support pattern 330 by the third horizontal separation distance DL3 less than the second horizontal separation distance DL2. The first horizontal separation distance DL1 may be greater than the side surface thickness TL, and each of the second horizontal separation distance DL2 and the third horizontal separation distance DL3 may be less than the side surface thickness TL.

At the same vertical level, a horizontal area of each of the plurality of third contact holes MCH3 and the plurality of third wiring contact plugs 430 may be less than a horizontal area of each of the plurality of second contact holes MCH2 and the plurality of second wiring contact plugs 420, respectively, and a horizontal area of each of the plurality of second contact holes MCH2 and the plurality of second wiring contact plugs 420 may be less than a horizontal area of each of the plurality of first contact holes MCH1 and the plurality of first wiring contact plugs 410, respectively. When the plurality of first contact holes MCH1, the plurality of second contact holes MCH2, and the plurality of third contact holes MCH3 are formed together, due to differences between the horizontal areas thereof, an extension length of the plurality of third contact holes MCH3 may be formed less than an extension length of the plurality of second contact holes MCH2, and the extension length of the plurality of second contact holes MCH2 may be less than an extension length of the plurality of first contact holes MCH1. Accordingly, each of the plurality of first wiring contact plugs 410 may have the same first vertical height H1 in the vertical direction (Z direction), each of the plurality of second wiring contact plugs 420 may have the second vertical height H2 less than the first vertical height H1 in the vertical direction (Z direction), and each of the plurality of third wiring contact plugs 430 may have a third vertical height H3 less than the second vertical height H2 in the vertical direction (Z direction).

From the upper surface of a portion of the capacitor dielectric layer 220 covering the upper surface of the upper support pattern 330 and the upper surface of the lower electrode 210, the lower surface of each of the plurality of first wiring contact plugs 410 may be apart by the same separation distance as the first vertical separation distance DV1 in the vertical direction (Z direction), the lower surface of each of the plurality of second wiring contact plugs 420 may be apart by the second vertical separation distance DV2 in the vertical direction (Z direction), and a lower surface of each of the plurality of third wiring contact plugs 430 may be apart by a third vertical separation distance DV3 in the vertical direction (Z direction). The first vertical separation distance DV1, the second vertical separation distance DV2, and the third vertical separation distance DV3 may generally have the same value.

Because separation distances between each of the plurality of first wiring contact plugs 410, the plurality of second wiring contact plugs 420, and the plurality of third wiring contact plugs 430, and the capacitor dielectric layer 220 are generally the same, the deviation of electrical characteristics of each of the plurality of capacitor structures 200 constituting the plurality of memory cells may be reduced, and thus, the reliability of the semiconductor memory device 1000c according to the inventive concept may be secured.

While the inventive concept has been particularly shown and described with reference to embodiments thereof, it will be understood that various change in form and details may be made therein without departing from the spirit and scope of the following claims.

What is claimed is:

1. A semiconductor memory device comprising:
a substrate including a memory cell region;
a plurality of lower electrodes arranged in the memory cell region of the substrate;
a support pattern in contact with upper end sidewalls of the plurality of lower electrodes to support the plurality of lower electrodes;
a capacitor dielectric layer covering the plurality of lower electrodes and the support pattern;
an upper electrode covering the plurality of lower electrodes and the support pattern with the capacitor dielectric layer therebetween;
a cover insulating layer covering the upper electrode;
a plurality of first wiring contact plugs configured to penetrate the cover insulating layer and extend into the upper electrode; and
a plurality of wiring lines arranged on the upper electrode and the plurality of first wiring contact plugs, at least some of the plurality of wiring lines connected to the plurality of first wiring contact plugs,
wherein, in a plan view, the plurality of first wiring contact plugs are apart from an edge of the support pattern into the support pattern by at least a first horizontal separation distance, and
wherein the first horizontal separation distance is greater than a side surface thickness that is a thickness of a portion of the upper electrode covering side surfaces of the support pattern in a horizontal direction.

2. The semiconductor memory device of claim 1, wherein,
in the plan view, the support pattern has a first thickness therein, and has a second thickness greater than the first thickness on an edge thereof.

3. The semiconductor memory device of claim 2, wherein the plurality of first wiring contact plugs are arranged on portions where the support pattern has the first thickness.

4. The semiconductor memory device of claim 1, wherein
each of the plurality of first wiring contact plugs is apart from an upper surface of the capacitor dielectric layer by an identical separation distance in a vertical direction.

5. The semiconductor memory device of claim 1, wherein
at least one of the plurality of wiring lines has a greater horizontal width than that of a remainder of the plurality of wiring lines, and the plurality of first wiring contact plugs are connected to the at least one of the plurality of wiring lines having the greater horizontal width.

6. The semiconductor memory device of claim 1, wherein,
in a plan view, an upper surface of first portions of the support pattern inside the support pattern is at a first vertical level, and an upper surface of second portions of the support pattern on the edge of the support pattern is at a second vertical level higher than the first vertical level, and
wherein the plurality of first wiring contact plugs are arranged on the first portions of the support pattern.

7. The semiconductor memory device of claim 1, further comprising
a plurality of second wiring contact plugs configured to penetrate the cover insulating layer and extend into the upper electrode, the plurality of second wiring contact plugs connected to at least one of the plurality of wiring lines,
wherein, in a plan view, the plurality of second wiring contact plugs are apart from an edge of the support pattern into the support pattern by the first horizontal separation distance and by a second separation distance less than the side surface thickness.

8. The semiconductor memory device of claim 7, wherein
a horizontal area and a vertical height of each of the plurality of second wiring contact plugs are less than a horizontal area and a vertical height of each of the plurality of first wiring contact plugs, respectively.

9. The semiconductor memory device of claim 8,
wherein each of the plurality of first wiring contact plugs is apart from an upper surface of the capacitor dielectric layer by an identical first vertical separation distance in a vertical direction,
wherein each of the plurality of second wiring contact plugs is apart from an upper surface of the capacitor dielectric layer by a second vertical separation distance in the vertical direction, and
wherein the first vertical separation distance is substantially same as the second vertical separation distance.

10. The semiconductor memory device of claim 1, wherein the first horizontal separation distance is about 300 nm.

11. A semiconductor memory device comprising:
a substrate;
a plurality of lower electrodes arranged on the substrate;
a support pattern in contact with upper end sidewalls of the plurality of lower electrodes to support the plurality of lower electrodes;
a capacitor dielectric layer covering the plurality of lower electrodes and the support pattern;
an upper electrode covering the plurality of lower electrodes and the support pattern with the capacitor dielectric layer therebetween;
a cover insulating layer covering the upper electrodes;
in a plan view, a plurality of first wiring contact plugs arranged apart from an edge of the support pattern into the support pattern by at least a first horizontal separation distance, the plurality of first wiring contact plugs configured to penetrate the cover insulating layer and extend into the upper electrode;
in a plan view, a plurality of second wiring contact plugs arranged apart from an edge of the support pattern into the support pattern by a second horizontal separation distance less than the first horizontal separation distance, the plurality of second wiring contact plugs configured to penetrate the cover insulating layer and extend into the upper electrode; and
a plurality of wiring lines arranged on the upper electrode, the plurality of first wiring contact plugs, and the plurality of second wiring contact plugs, at least one of the plurality of wiring lines connected to the plurality of first wiring contact plugs and the plurality of second wiring contact plugs,
wherein the first horizontal separation distance is greater than a side surface thickness that is a thickness of a portion of the upper electrode covering side surfaces of the support pattern in a horizontal distance, and
wherein a vertical height of each of the plurality of second wiring contact plugs is less than a vertical height of each of the plurality of first wiring contact plugs.

12. The semiconductor memory device of claim 11,
wherein, in a plan view, the support pattern has a first thickness therein, and has a second thickness greater than the first thickness on an edge thereof,
wherein the plurality of first wiring contact plugs are arranged on portions where the support pattern has the first thickness, and
wherein the second horizontal separation distance is less than the side surface thickness.

13. The semiconductor memory device of claim 11, wherein
each of the plurality of first wiring contact plugs and each of the plurality of second wiring contact plugs are apart from an upper surface of the capacitor dielectric layer by a substantially same vertical separation distance in a vertical direction.

14. The semiconductor memory device of claim 13, wherein
a horizontal area of each of the plurality of second wiring contact plugs is less than a horizontal area of each of the plurality of first wiring contact plugs.

15. The semiconductor memory device of claim 11, wherein,
in a plan view, an upper surface of portions of the support pattern inside the support pattern is at a first vertical level, and an upper surface of the support pattern on the edge of the support pattern is at a second vertical level higher than the first vertical level by about 10 nm to about 30 nm, and
wherein the plurality of first wiring contact plugs are arranged on the portions where the upper surface of the support pattern is at the first vertical level.

16. The semiconductor memory device of claim 11, further comprising
a plurality of third wiring contact plugs configured to penetrate the cover insulating layer and extend into the upper electrode, the plurality of third wiring contact plugs connected to some of the plurality of wiring lines,
wherein, in a plan view, the plurality of third wiring contact plugs are apart from an edge of the support pattern into the support pattern by a third horizontal separation distance less than each of the second horizontal separation distance and the side surface thickness, and
wherein a vertical height of each of the plurality of third wiring contact plugs is less than a vertical height of each of the plurality of second wiring contact plugs.

17. The semiconductor memory device of claim 16, wherein
each of the plurality of first wiring contact plugs, the plurality of second wiring contact plugs, and the plurality of third wiring contact plugs are apart from the upper surface of the capacitor dielectric layer by substantially a same vertical separation distance in a vertical direction, and
wherein a horizontal area of each of the plurality of third wiring contact plugs is less than a horizontal area of each of the plurality of second wiring contact plugs, and the horizontal area of each of the plurality of second wiring contact plugs is less than a horizontal area of each of the plurality of first wiring contact plugs.

18. A semiconductor memory device comprising:
a substrate in which a plurality of active regions are limited;
a plurality of word lines configured to respectively cross the plurality of active regions and extend in a first horizontal direction;
a plurality of bit lines respectively arranged in the plurality of active regions, and extending in a second horizontal direction orthogonal to the first horizontal direction;
a plurality of buried contacts configured to fill lower side portions of spaces between each of the plurality of bit lines, the plurality of buried contacts respectively connected to the plurality of active regions;
a plurality of landing pads configured to fill upper side portions of spaces between each of the plurality of bit lines, the plurality of landing pads respectively extending onto the plurality of bit lines;
a plurality of lower electrodes respectively in contact with the plurality of landing pads;
a support pattern in contact with upper end sidewalls of the plurality of lower electrodes to support the plurality of lower electrodes;
a capacitor dielectric layer covering the plurality of lower electrodes and the support pattern;
an upper electrode covering the plurality of lower electrodes and the support pattern with the capacitor dielectric layer therebetween;
a cover insulating layer covering the upper electrode;
in a plan view, a plurality of first wiring contact plugs arranged apart from an edge of the support pattern into the support pattern by at least a first horizontal separation distance, the plurality of first wiring contact plugs configured to penetrate the cover insulating layer and extend into the upper electrode;
in a plan view, a plurality of second wiring contact plugs arranged apart from an edge of the support pattern into the support pattern by a second horizontal separation distance less than the first horizontal separation distance, the plurality of first wiring contact plugs configured to penetrate the cover insulating layer and extend into the upper electrode; and
a plurality of wiring lines arranged on the upper electrode, the plurality of first wiring contact plugs, and the plurality of second wiring contact plugs, at least one of the plurality of wiring lines connected to the plurality of first wiring contact plugs and the plurality of second wiring contact plugs,
wherein the first horizontal separation distance is greater than a side surface thickness, that is a thickness of a portion of the upper electrode covering side surfaces of the support pattern in a horizontal direction, and the second horizontal separation distance is less than the side surface thickness, and
wherein a horizontal area of each of the plurality of second wiring contact plugs is less than a horizontal area of each of the plurality of first wiring contact plugs.

19. The semiconductor device of claim 18,
wherein the first horizontal separation distance is greater than a side surface thickness, that is a thickness of a portion of the upper electrode covering side surfaces of the support pattern in a horizontal direction, and the second horizontal separation distance is greater than the side surface thickness.

20. The semiconductor memory device of claim 18,
wherein a vertical height of each of the plurality of second wiring contact plugs is less than a vertical height of each of the plurality of first wiring contact plugs, and
wherein each of the plurality of first wiring contact plugs and each of the plurality of second wiring contact plugs are apart from an upper surface of the capacitor dielectric layer by substantially a same vertical separation distance in a vertical direction.
